(19) United States
(12) Patent Application Publication
(10) Pub. No.: US 2026/0262223 A1
(43) Pub. Date: Sep. 3, 2026

(54) SEMICONDUCTOR MEMORY DEVICE AND ELECTRONIC SYSTEM INCLUDING THE SAME

(71) Applicant: Samsung Electronics Co., Ltd., Suwon-si (KR)

(72) Inventors: Sanghun CHUN, Suwon-si (KR); Hyunji KIM, Suwon-si (KR); Hyeongjin KIM, Suwon-si (KR); Woongrae JO, Suwon-si (KR); Jeehoon HAN, Suwon-si (KR)

(73) Assignee: Samsung Electronics Co., Ltd., Suwon-si (KR)

(21) Appl. No.: 19/311,546

(22) Filed: Aug. 27, 2025

(30) Foreign Application Priority Data
Feb. 28, 2025 (KR) 10-2025-0026387

(51) Int. Cl. H10B 43/35; H01L 23/00; H01L 25/00; H01L 25/065; H01L 25/18; H10B 43/10; H10B 43/27; H10B 80/00

(52) U.S. Cl. CPC H10B 43/35; H10B 43/10; H10B 43/27; H10B 80/00; H10W 90/00; H10W 80/312; H10W 80/327; H10W 90/792

(57) ABSTRACT

A semiconductor memory device includes a cell lower insulating layer including a cell array region and an extension region, a plurality of gate electrodes stacked on the cell lower insulating layer, a channel structure penetrating the plurality of gate electrodes, a word line contact on the extension region and penetrating a portion of gate electrodes, defining a gate isolation trench penetrating the plurality of gate electrodes and extending in a first horizontal direction, an air gap between the plurality of gate electrodes and in the gate isolation trench, a source plate structure defining an opening communicatively coupled to the gate isolation trench, on one end of the channel structure, and extending in a second horizontal direction, and a cell upper insulating layer on the source plate structure and covering the opening. The air gap is on the cell array region and the extension region.

### CROSS-REFERENCE TO RELATED APPLICATIONS

This application claims priority to Korean Patent Application No. 10-2025-0026387, filed in the Korean Intellectual Property Office on Feb. 28, 2025, the entire contents of which are hereby incorporated by reference.

### BACKGROUND

Some example embodiments relate to a semiconductor memory device and/or an electronic system including the same.

There is a desire for a semiconductor memory device capable of storing high-capacity data in an electronic system that uses data storage. Accordingly, research is being conducted to increase the data storage capacity of the semiconductor memory device. For example, a semiconductor device has been proposed as one of the methods for increasing the data storage capacity of the semiconductor device, which includes three-dimensional arrangement of memory cells instead of two-dimensional arrangement of memory cells.

### SUMMARY

In order to improve upon one or more problems (e.g., the problems described above and/or other problems not explicitly described herein), some example embodiments provide a semiconductor memory device having improved electrical characteristics and reliability.

Alternatively or additionally in order to improve upon one or more problems (e.g., the problems described above and/or other problems not explicitly described herein), some example embodiments provide an electronic system having improved electrical characteristics and reliability.

Alternatively or additionally in order to improve upon one or more problems (e.g., the problems described above and/or other problems not explicitly described herein), some example embodiments provide a method for manufacturing a semiconductor memory device having improved electrical characteristics and reliability.

According to some example embodiments, a semiconductor memory device may include a cell lower insulating layer including a cell array region and an extension region, a plurality of gate electrodes stacked spaced apart from each other on the cell lower insulating layer, a channel structure on the cell array region and penetrating the plurality of gate electrodes, a word line contact on the extension region and penetrating a portion of gate electrodes among the plurality of gate electrodes, a gate isolation trench penetrating the plurality of gate electrodes and extending in a first horizontal direction, an air gap between the plurality of gate electrodes and disposed in the gate isolation trench, a source plate structure defining an opening communicatively coupled to the gate isolation trench, on one end of the channel structure, and extending in a second horizontal direction that intersects the first horizontal direction, and a cell upper insulating layer disposed on the source plate structure and covering the opening, wherein the air gap is on the cell array region and the extension region.

Alternatively or additionally according to some example embodiments, a semiconductor memory device may include a cell lower insulating layer including a cell array region and an extension region, a barrier layer on the cell lower insulating layer, a plurality of gate electrodes stacked and spaced apart from each other on the barrier layer, a channel structure on the cell array region and penetrating the plurality of gate electrodes, a word line contact on the extension region and connected to one of the plurality of gate electrodes, defining a gate isolation trench penetrating the plurality of gate electrodes and extending in a first horizontal direction, an air gap between at least some of the plurality of gate electrodes and in the gate isolation trench, a source plate structure disposed on one end of the channel structure, extending in a second horizontal direction intersecting the first horizontal direction, and the source plate structure defining an opening communicatively coupled to the gate isolation trench, and a cell upper insulating layer on the source plate structure and covering the opening, wherein the air gap is on the cell array region and the extension region.

Alternatively or additionally according to some example embodiments, an electronic system may include a main substrate, a semiconductor memory device mounted on the main substrate, the semiconductor memory device including a peripheral circuit structure and a cell structure stacked on the peripheral circuit structure, and a controller mounted on the main substrate and electrically connected to the semiconductor memory device, wherein the cell structure includes, a cell lower insulating layer including a cell array region and an extension region, a barrier layer on the cell lower insulating layer, a plurality of gate electrodes stacked spaced apart from each other on the barrier layer, a channel structure on the cell array region and penetrating the plurality of gate electrodes, a word line contact disposed on the extension region and connected to one of the plurality of gate electrodes, defining a gate isolation trench penetrating the plurality of gate electrodes and extending in a first horizontal direction, an air gap between at least some of the plurality of gate electrodes and in the gate isolation trench, a source plate structure on one end of the channel structure, extending in a second horizontal direction intersecting the first horizontal direction, the source plate structure defining an opening communicatively coupled to the gate isolation trench, and a cell upper insulating layer on the source plate structure and covering the opening, wherein the air gap is on the cell array region and the extension region.

Alternatively or additionally according to some example embodiments, a method for manufacturing a semiconductor memory device may include forming a mold structure including a plurality of gate electrodes and a plurality of mold insulating layers alternately stacked on a substrate, forming a channel structure and a gate isolation structure on the substrate, forming a barrier layer extending along a lower surface of the mold structure, a lower surface of the channel structure, and a lower surface of the gate isolation structure, forming a cell lower insulating layer under the barrier layer, coupling a peripheral circuit structure under the cell lower insulating layer, removing the substrate and forming a source plate structure, removing a portion of the source plate structure to form an opening, wherein the opening exposes an upper surface of the gate isolation structure, removing the gate isolation structure and forming a gate isolation trench, removing at least a portion of the plurality of mold insulating layers, and forming a cell upper insulating layer on the source plate structure.

Alternatively or additionally according to some example embodiments, removing at least a portion of the plurality of mold insulating layers may include performing an etching process through the gate isolation trench to remove at least a portion of the plurality of mold insulating layers.

Alternatively or additionally according to some example embodiments, an etchant used in the etching process may have an etching selectivity with respect to the plurality of mold insulating layers and the barrier layer.

Alternatively or additionally according to some example embodiments, forming the channel structure may include forming a channel hole that penetrates the mold structure, forming a first high-k insulating film in the channel hole, and forming an information storage film and a semiconductor pattern in the first high-k insulating film.

Alternatively or additionally according to some example embodiments, before forming the barrier layer, the method may further include removing a portion of the gate isolation structure, and a lower surface of the gate isolation structure may be disposed at a higher vertical level than a lower surface of the mold structure.

Alternatively or additionally according to some example embodiments, forming the source plate structure may include removing the substrate to expose one end of the channel structure and one end of the gate isolation structure, removing one end of the channel structure to expose the semiconductor pattern of the channel structure, forming a semiconductor layer covering the exposed semiconductor pattern and the exposed one end of the gate isolation structure, and forming a conductive layer on the semiconductor layer.

Alternatively or additionally according to some example embodiments, before forming the barrier layer, the method may further include forming a support structure that penetrates the mold structure, and forming the support structure may include forming a support structure hole that penetrates the mold structure, forming a second high-k insulating film in the support structure hole, and forming the support structure in the second high-k insulating film.

Alternatively or additionally according to some example embodiments, the cell upper insulating layer may cover the opening of the source plate structure.

Alternatively or additionally according to some example embodiments, an upper surface of the channel structure may be disposed at the same vertical level as an upper surface of the gate isolation structure.

Alternatively or additionally according to some example embodiments, an upper surface of the channel structure may be disposed at a higher vertical level than an upper surface of the gate isolation structure.

Alternatively or additionally according to some example embodiments, by placing an air gap between the plurality of gate electrodes, the electrical characteristics and reliability of the semiconductor memory device may be improved.

According to some example embodiments, by placing air gaps over both a cell array region and an extension region, the electrical characteristics and/or the reliability of the semiconductor memory device may be improved.

### BRIEF DESCRIPTION OF THE DRAWINGS

The above and other features of inventive concepts will become more apparent by describing in detail some example embodiments thereof with reference to the attached drawings, in which:

FIG. 1 illustrates an example plan view of a semiconductor memory device according to some example embodiments;

FIG. 2 is a cross-sectional view illustrating FIG. 1 taken along line A-A;

FIG. 3 is a cross-sectional view illustrating FIG. 1 taken along lines B-B and C-C;

FIGS. 4 and 5 illustrate enlarged views of region Q1 in FIG. 1;

FIGS. 6-8 illustrate enlarged views of region Q2 in FIG. 1;

FIG. 9 illustrates an enlarged view of region Q3 in FIG. 2;

FIGS. 10 and 11 are diagrams illustrating a semiconductor memory device according to some example embodiments;

FIGS. 12 and 13 are diagrams illustrating a semiconductor memory device according to some example embodiments;

FIG. 14 is a diagram illustrating a semiconductor memory device according to some example embodiments;

FIGS. 15 and 16 are diagrams illustrating a semiconductor memory device according to some example embodiments;

FIG. 17 is a diagram illustrating a semiconductor memory device according to some example embodiments;

FIGS. 18 to 33 are diagrams illustrating a method for manufacturing a semiconductor memory device according to some example embodiments;

FIGS. 34 and 35 are diagrams illustrating a method of manufacturing a semiconductor memory device according to some example embodiments;

FIGS. 36 and 37 are diagrams illustrating a method of manufacturing a semiconductor memory device according to some example embodiments;

FIG. 38 is an example block diagram illustrating an electronic system according to some example embodiments;

FIG. 39 is an example perspective view illustrating an electronic system including a semiconductor memory device according to some example embodiments;

FIG. 40 is a schematic cross-sectional view illustrating FIG. 39 taken along line V-V.

### DETAILED DESCRIPTION

As used herein, terms such as upper, lower, upper surface, and lower surface are used for convenience of description and are not limiting. Upper, lower, upper surface, and lower surface are described based on what is shown in the drawings, and these terms may change when the drawings are turned upside down.

Hereinafter, with reference to the drawings, a semiconductor device according to some example embodiments and/or a method of manufacturing the same will be described in detail.

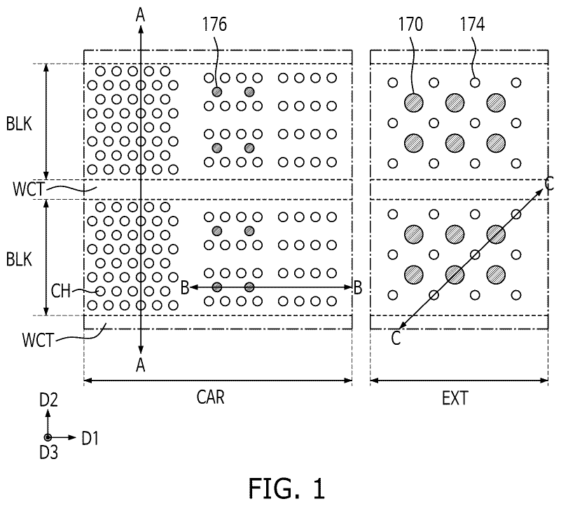

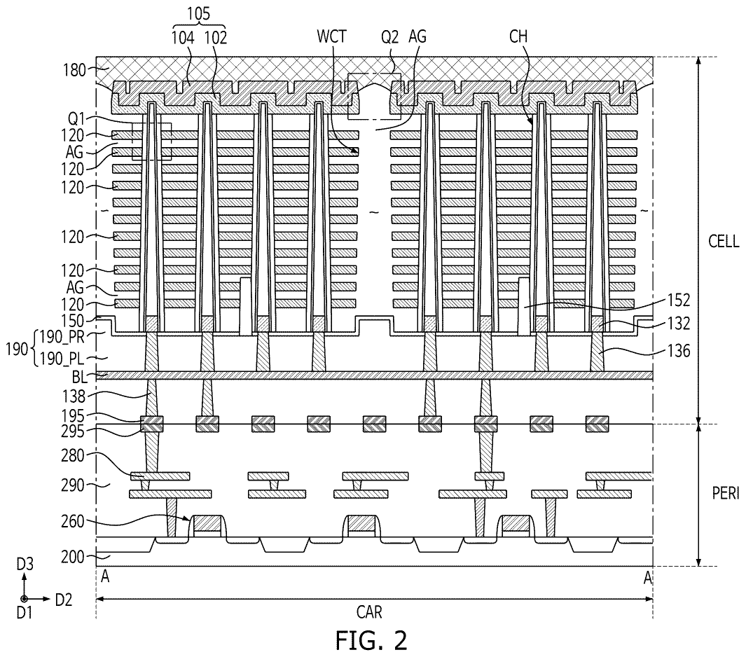

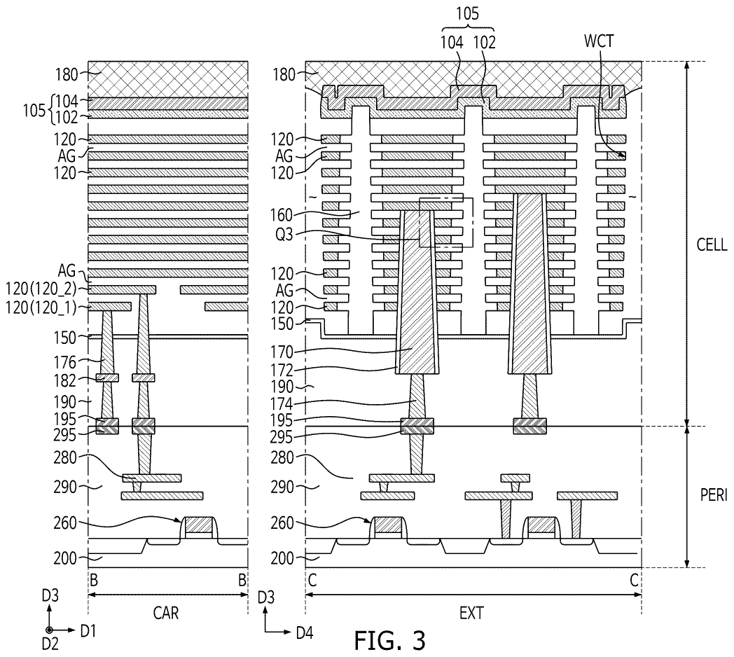

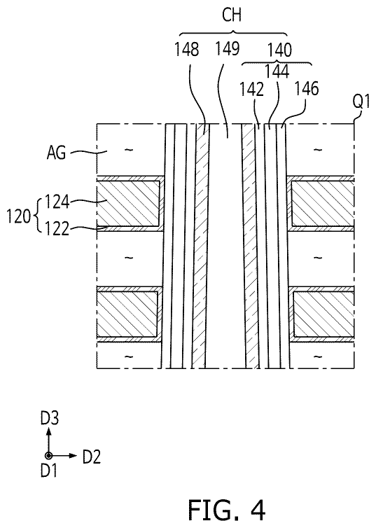

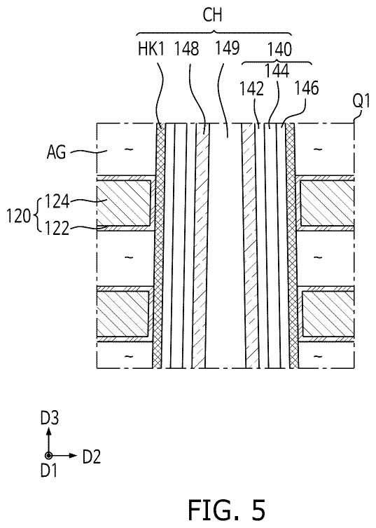

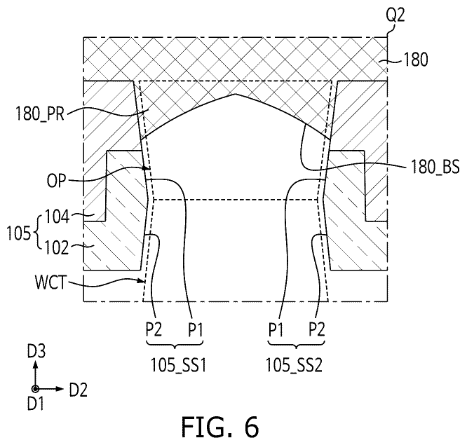

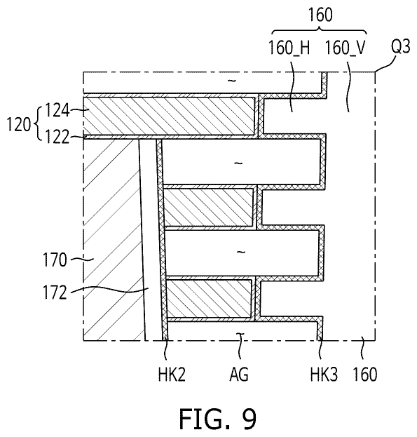

FIG. 1 illustrates an example plan view of a semiconductor memory device according to some example embodiments. FIG. 2 is a cross-sectional view illustrating FIG. 1 taken along line A-A. FIG. 3 is a cross-sectional view illustrating FIG. 1 taken along lines B-B and C-C. FIGS. 4 and 5 illustrate enlarged views of region Q1 in FIG. 1. FIGS. 6-8 illustrate enlarged views of region Q2 in FIG. 1. FIG. 9 illustrates an enlarged view of region Q3 in FIG. 2.

Referring to FIGS. 1-9, a semiconductor memory device according to some example embodiments may include a cell structure CELL and a peripheral circuit structure PERI.

The cell structure CELL may include a plurality of gate electrodes 120, an air gap AG, a gate isolation trench WCT, a source plate structure 105, an upper cell insulating layer 180, a channel structure CH, a bit line contact 136, a bit line BL, a cell via 134, a barrier layer 150, a support structure 160, a word line contact 170, a first bonding pad 195, and a cell lower insulating layer 190.

The cell structure CELL may include a cell array region CAR and an extension region EXT. For example, the cell lower insulating layer 190 may include the cell array region CAR and the extension region EXT. The cell array region CAR may be or may include, or be included in a region in which the channel structure CH is disposed, and the extension region EXT may be or may include, or be included in a region in which the word line contact 170 is disposed.

The plurality of gate electrodes 120 may be disposed over the cell array region CAR and the extension region EXT. The plurality of gate electrodes 120 may be disposed spaced apart from one another in a third direction D3 on the cell lower insulating layer 190. Each of the plurality of gate electrodes 120 may be spaced apart from each other in the third direction D3. A thickness of and/or a material composition of each of the plurality of gate electrodes 120 may be the same, or, alternatively, at least one of a thickness of or a material composition of at least one of the plurality of gate electrodes 120 may be different than at least one other of the plurality of gate electrodes 120. An air gap AG may be disposed between the plurality of gate electrodes 120. The airgap AG may be contiguous between ones of the plurality of gate electrodes 120; however, example embodiments are not limited thereto. Each of the plurality of gate electrodes 120 may extend in a first direction D1 and a second direction D2. Each of the plurality of gate electrodes 120 may have a structure extending in a direction parallel to an upper surface of a peripheral circuit substrate 200.

The first direction D1 and the second direction D2 may each be parallel to the upper surface of the peripheral circuit substrate 200. The first direction D1 maybe perpendicular to the second direction D2; example embodiments are not limited thereto. The third direction D3 may be perpendicular to each of the first direction D1 and the second direction D2. The third direction D3 may be perpendicular to the upper surface of the peripheral circuit substrate 200. In some example embodiments, the first direction D1 and the second direction D2 may be referred to as the first horizontal direction and the second horizontal direction, respectively, and the third direction D3 may be referred to as the vertical direction.

In some example embodiments, at least one, or some gate electrodes 120 among the plurality of gate electrodes 120 may be provided as a ground select line GSL of the semiconductor memory device. At least one other, such as other gate electrodes 120 among the plurality of gate electrodes 120 may be provided as a string select line SSL of the semiconductor memory device. For example, among the plurality of gate electrodes 120, the gate electrode 120 adjacent to the source plate structure 105 may be provided as the ground select line GSL. Among the plurality of gate electrodes 120, the gate electrode 120 adjacent to the bit line BL may be provided as the string select line SSL. However, example embodiments are not limited thereto. The arrangement and the number of ground select lines GSL and string select lines SSL may vary.

In some example embodiments, some gate electrodes 120 among the plurality of gate electrodes 120 may be used as an erase control line ECL of the semiconductor memory device. The erase control line ECL may be used as the gate electrode of an erase transistor. The erase transistor may generate gate induced drain leakage GIDL and perform an erase operation of a plurality of memory cell transistors.

In some example embodiments, each gate electrode 120 may include an electrode barrier layer 122 and an electrode filling layer 124. The electrode barrier layer 122 may be disposed along an outer side surface of the gate electrode 120. For example, the electrode barrier layer 122 may be disposed on the air gap AG and may contact the channel structure CH. The electrode filling layer 124 may fill an inner space of the electrode barrier layer 122. In some cases, the electrode filling layer 124 may be conformal with respect to the electrode barrier layer 122.

The electrode barrier layer 122 may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbon nitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material.

The electrode filling layer 124 may include, for example, at least one of aluminum (Al), tungsten (W), cobalt (Co), ruthenium (Ru), silver (Ag), gold (Au), manganese (Mn), and molybdenum (Mo), and in some cases, there may be an interface, such as a sharp interface, between the electrode filling layer 124 and the electrode barrier layer 122.

The channel structure CH may be disposed on the cell lower insulating layer 190. The channel structure CH may penetrate the plurality of gate electrodes 120 and may extend in the third direction D3. The channel structure CH may intersect the plurality of gate electrodes 120. The channel structure CH may be disposed in a channel hole extending in the third direction D3. The channel structure CH may have a pillar shape (e.g., a cylindrical shape or an elliptically cylindrical shape) extending in the third direction D3.

In some example embodiments, due to the high aspect ratio of the stacked plurality of gate electrodes 120, the cross section of the channel structure CH may have slanted side surfaces that become narrower as being closer to the source plate structure 105. However, example embodiments are not limited thereto. In some example embodiments, the channel structure CH may be tapered; however, example embodiments are not limited thereto.

Referring to FIGS. 2 and 4, the channel structure CH may include an information storage film 140, a semiconductor pattern 148, and a filling pattern 149.

The semiconductor pattern 148 may extend in the third direction D3 and may penetrate the plurality of gate electrodes 120. One end of the semiconductor pattern 148 may penetrate a lower surface of the source plate structure 105. One end of the semiconductor pattern 148 may be disposed in the source plate structure 105. The semiconductor pattern 148 may be connected to a semiconductor layer 102 of the source plate structure 105. Although the semiconductor pattern 148 is illustrated as having a cup shape, example embodiments are not limited thereto. The semiconductor pattern 148 may have various shapes, such as one or more of a cylindrical shape, a rectangular prism shape, or a solid pillar shape, for example. The semiconductor pattern 148 may include, for example, a semiconductor material such as one or more of single-crystal silicon, polycrystalline silicon, an organic semiconductor material, or a carbon nano structure, but example embodiments are not limited thereto. In some example embodiments, the semiconductor pattern 148 may be doped with impurities; however, example embodiments are not limited thereto.

The information storage film 140 may be interposed between the semiconductor pattern 148 and the gate electrode 120, and between the semiconductor pattern 148 and the air gap AG. For example, the information storage film 140 may extend along an outer side surface of the semiconductor pattern 148. The information storage film 140 may include, for example, at least one of a silicon oxide, a silicon nitride, a silicon oxynitride, or a high-k material having a higher dielectric constant than silicon oxide. In some cases, the information storage film 148 may be doped with impurities; however, example embodiments are not limited thereto. The high-k material may include, for example, at least one of aluminum oxide, hafnium oxide, lanthanum oxide, tantalum oxide, titanium oxide, lanthanum hafnium oxide, lanthanum aluminum oxide, dysprosium scandium oxide, or combinations thereof. The information storage film 140 may be capable of storing a single bit of data as a single-level cell (SLC), or of storing multi-bit data as a multi-level cell (MLC); however, example embodiments are not limited thereto.

In some example embodiments, from a plan view perspective, the channel structures CH may be arranged in a zigzag form. For example, the channel structures CH may be arranged in a staggered manner in the first direction D1 and the second direction D2. The zigzag arrangement of the channel structures CH may further enhance and/or improve upon the integration density of the semiconductor memory device. In some example embodiments, the channel structures CH may be arranged in a honeycomb pattern.

In some example embodiments, the information storage film 140 may be formed as a multi-layer film. The information storage film 140 may include a tunnel insulating film 142, a charge storage film 144, and a blocking insulating film 146, which are sequentially stacked on an outer side surface of the semiconductor pattern 148.

The tunnel insulating film 142 may include, for example, a silicon oxide and/or a high-k material having a dielectric constant higher than that of silicon oxide (e.g., one or more of aluminum oxide (Al2O3), hafnium oxide (HfO2)). The charge storage film 144 may include, for example, a silicon nitride. The blocking insulating film 146 may include, for example, a silicon oxide and/or a high-k material having a dielectric constant higher than that of silicon oxide (e.g., aluminum oxide (Al2O3) and/or hafnium oxide (HfO2)).

In some example embodiments, the channel structure CH may further include the filling pattern 149. The filling pattern 149 may be formed so as to fill the interior of the cup-shaped semiconductor pattern 148. The filling pattern 149 may include an insulating material, for example, a silicon oxide, but example embodiments are not limited thereto.

Referring to FIG. 5, in some example embodiments, the channel structure CH may further include a first high-k insulating film HK1. The first high-k insulating film HK1 may be disposed on an outer side surface of the information storage film 140. The first high-k insulating film HK1 may define an outer side surface of the channel structure CH. For example, the first high-k insulating film HK1 may surround the information storage film 140. The first high-k insulating film HK1 may be disposed between the gate electrode 120 and the information storage film 140, and between the air gap AG and the information storage film 140.

Referring again to FIGS. 1-9, the gate isolation trench WCT may be disposed on the cell lower insulating layer 190. For example, the gate isolation trench WCT may be disposed on a second protrusion 190_PR of the cell lower insulating layer 190. The gate isolation trench WCT may extend in the third direction D3 and may penetrate the plurality of gate electrodes 120. For example, the gate isolation trench WCT may extend in the first direction D1 and the third direction D3 to isolate the plurality of gate electrodes 120. One end of the gate isolation trench WCT may be disposed on the source plate structure 105.

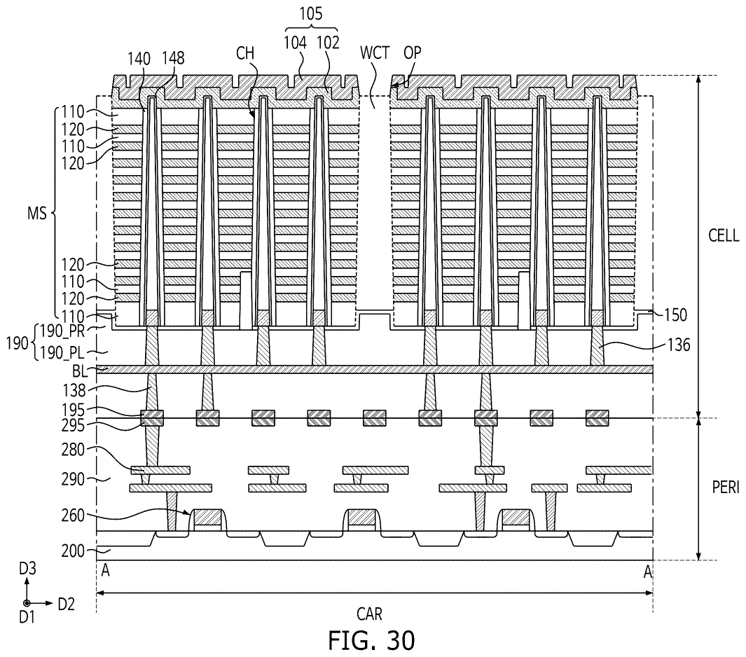

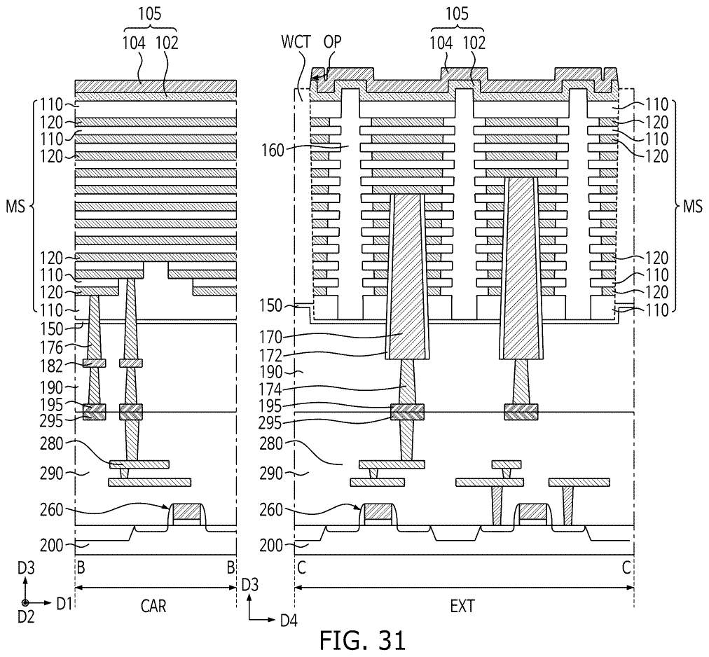

As shown in FIG. 1, the gate isolation trench WCT may extend in the first direction D1 and be disposed over the cell array region CAR and the extension region EXT. The gate isolation trench WCT may define a cell block BLK. For example, a cell block BLK may be defined between gate isolation trenches WCT that are adjacent in the second direction D2. A detailed description of defining the gate isolation trench WCT will be provided with reference to FIGS. 30 and 31.

The air gap AG may be disposed over the cell array region CAR and the extension region EXT of the cell lower insulating layer 190. The air gap AG may be disposed on the barrier layer 150. The air gap AG may be disposed between each of the plurality of gate electrodes 120, between the gate electrode 120 and the barrier layer 150, and between the gate electrode 120 and the source plate structure 105. The air gap AG may be disposed within the gate isolation trench WCT. Each of the plurality of gate electrodes 120 may be spaced apart from each other in the third direction D3 by the air gap AG. The air gap AG may be referred to, for example, as an empty space or a cavity. The air gap AG may include air, such as but not limited to nitrogen and/or clean, dry air (CDA). Example embodiments are not limited thereto. Alternatively or additionally, the air gap AG may include an inert gas, such as an inert gas in trace amounts; however, example embodiments are not limited thereto.

In the semiconductor memory device according to some example embodiments, the air gap AG may be disposed between the plurality of gate electrodes 120. For example, the air gap AG may be disposed between the plurality of gate electrodes 120 in the cell array region CAR and the extension region EXT. Because an air gap AG having a dielectric constant lower than that of silicon oxide is disposed between the plurality of gate electrodes 120, the resistor-capacitor (RC) delay and/or the read time of the semiconductor memory device may be improved. Alternatively or additionally, because the air gap AG is disposed in both the cell array region CAR and the extension region EXT, the capacitance of the gate electrodes 120 may be improved. For example, the electrical characteristics of the semiconductor memory device may be improved.

The source plate structure 105 may be disposed over the cell array region CAR and the extension region EXT. The source plate structure 105 may be disposed at one end of the channel structure CH over the cell array region CAR. The source plate structure 105 may extend in the first direction D1 and the second direction D2. The source plate structure 105 may be connected to the gate isolation trench WCT.

The source plate structure 105 may include a plurality of layers. For example, the source plate structure 105 may include a semiconductor layer 102 and a conductive layer 104. The semiconductor layer 102 may contact one end of the channel structure CH. For example, the semiconductor layer 102 may be connected to the semiconductor pattern 148 of the channel structure CH. The semiconductor layer 102 may contact one end of a dummy support structure 160. The conductive layer 104 may extend along the profile of an upper surface of the semiconductor layer 102. Although the source plate structure 105 is described as including a plurality of layers, example embodiments are not limited thereto. For example, the source plate structure 105 may be formed of a single layer, e.g. of a single homogenous layer.

The cell upper insulating layer 180 may be disposed on the source plate structure 105. The cell upper insulating layer 180 may cover the source plate structure 105. For example, the cell upper insulating layer 180 may cover an opening OP of the source plate structure 105, which will be described later. By the cell upper insulating layer 180 covering the opening OP of the source plate structure 105, the air gap AG, which is disposed between the plurality of gate electrodes 120 and within the gate isolation trench WCT, may be blocked from the outside.

Referring to FIG. 6, the source plate structure 105 may include an opening OP. The opening OP of the source plate structure 105 may be connected (or communicatively coupled) to the gate isolation trench WCT. The opening OP of the source plate structure 105 may be defined by a first portion P1. The source plate structure 105 may include a first side surface 105_SS1 and a second side surface 105_SS2. The first side surface 105_SS1 may face the second side surface 105_SS2 in the second direction D2 (for example, the second horizontal direction).

Each of the first side surface 105_SS1 and the second side surface 105_SS2 may include a first portion P1 and a second portion P2. For convenience of description, the following focuses on the first side surface 105_SS1. The first portion P1 of the first side surface 105_SS1 may have a first slope, and the second portion P2 may have a second slope that is different from the first slope. The width of the opening OP in the second direction D2 may decrease as being farther away from the cell upper insulating layer 180. For example, the first portion P1 of the first side surface 105_SS1 may have a slope in which the width of the opening OP in the second direction D2 decreases. Meanwhile, the width of the gate isolation trench WCT in the second direction D2 may increase as being farther away from the cell upper insulating layer 180. The second portion P2 of the first side surface 105_SS1 may have a slope in which the width of the gate isolation trench WCT in the second direction D2 increases. There may be a vertex at a connection between the first portion P1 and the second portion P2; however, example embodiments are not limited thereto.

Although the first portion P1 and the second portion P2 of the first side surface 105_SS1 are illustrated as being connected on the semiconductor layer 102, example embodiments are not limited thereto. For example, the first portion P1 and the second portion P2 of the first side surface 105_SS1 may be connected on the conductive layer 104.

The cell upper insulating layer 180 may include a first protrusion 180_PR. The first protrusion 180_PR may be disposed on the opening OP of the source plate structure 105. The first protrusion 180_PR may fill at least a portion of the opening OP. The first protrusion 180_PR may overlap the source plate structure 105 in the first direction D1 and the second direction D2.

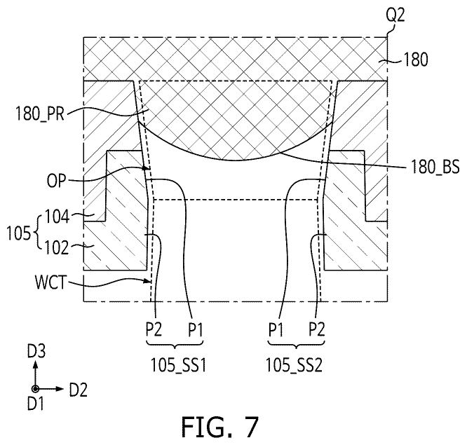

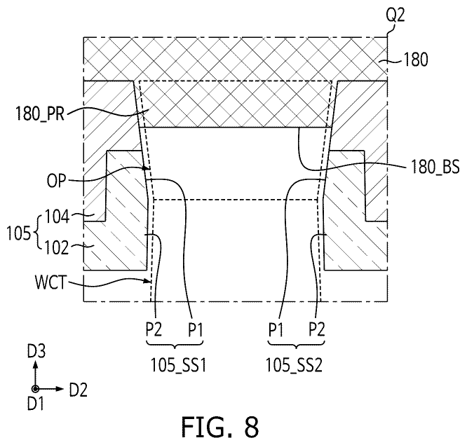

A lower surface of the first protrusion 180_PR may contact the air gap AG. A lower surface 180_BS of the first protrusion 180_PR may include a curved surface. In some example embodiments, as shown in FIG. 6, the lower surface 180_BS of the first protrusion 180_PR may include a concave curved surface. Alternatively or additionally in some example embodiments, as shown in FIG. 7, the lower surface 180_BS of the first protrusion 180_PR may include a convex curved surface. Alternatively or additionally in some example embodiments, as shown in FIG. 8, the lower surface 180_BS of the first protrusion 180_PR may include a flat plane.

Although the lower surface 180_BS of the first protrusion 180_PR is illustrated as being disposed on the first portion P1 of the first side surface 105_SS1, example embodiments are not limited thereto. For example, the first protrusion 180_PR may protrude such that the lower surface 180_BS of the first protrusion 180_PR is disposed on the second portion P2 of the first side surface 105_SS1.

The semiconductor layer 102 may include a semiconductor material. The semiconductor layer 102 may include, for example, polysilicon (Si) such as but not limited to doped polysilicon. The conductive layer 104 may include a metal. The conductive layer 104 may include, for example, one of tungsten (W), copper (Cu), aluminum (Al), or cobalt (Co). However, example embodiments are not limited thereto.

Referring again to FIGS. 1-9, the cell lower insulating layer 190 may be disposed on the other end of the channel structure CH. The barrier layer 150 may be disposed on the cell lower insulating layer 190. For example, the barrier layer 150 may be disposed between the cell lower insulating layer 190 and the air gap AG.

The cell lower insulating layer 190 may include a plate portion 190_PL and a second protrusion 190_PR. The plate portion 190_PL may extend in the first direction D1 and the second direction D2. The second protrusion 190_PR may protrude in the third direction D3 from the plate portion 190_PL toward the cell upper insulating layer 180. A distance from the lower surface of the cell lower insulating layer 190 to the upper surface of the second protrusion 190_PR may be greater than a distance from the lower surface of the cell lower insulating layer 190 to a lower surface of the channel structure CH. The second protrusion 190_PR may overlap or at least partially overlap the gate isolation trench WCT in the third direction D3.

The barrier layer 150 may be disposed on the cell lower insulating layer 190. The barrier layer 150 may extend along the upper surface of the cell lower insulating layer 190. For example, the barrier layer 150 may extend along the upper surface and side surface profiles of the plate portion 190_PL and the second protrusion 190_PR. By the barrier layer 150, the cell lower insulating layer 190 may not contact the air gap AG.

The barrier layer 150 may include a material having an etching selectivity with respect to silicon oxide. For example, the barrier layer 150 may include an insulating film such as aluminum oxide (aluminum oxide). In some example embodiments, the barrier layer 150 may include the same material as the first high-k insulating film HK1. However, example embodiments are not limited thereto. For example, the barrier layer 150 may include a material, such as silicon nitride (silicon nitride), that has an etching selectivity with respect to silicon oxide.

Each of the cell lower insulating layer 180 and the cell upper insulating layer 190 may include, for example, at least one of a silicon oxide, a silicon oxynitride, or a low-k material having a lower dielectric constant than silicon oxide, but example embodiments are not limited thereto.

A string isolation structure 152 may penetrate some gate electrodes 120 among the plurality of gate electrodes 120. For example, the string isolation structure 152 may penetrate two gate electrodes 120 disposed on a lower portion of the plurality of gate electrodes 120. Although the string isolation structure 152 is illustrated as penetrating two gate electrodes 120, example embodiments are not limited thereto. For example, the string isolation structure 152 may penetrate four gate electrodes 120 or more than four gate electrodes 120.

A channel pad 132 may be disposed on the channel structure CH. The channel pad 132 may be disposed at a lower portion of the channel structure CH and may be electrically connected to the semiconductor pattern 148. A bit line contact 136 may be disposed on the channel pad 132. The bit line contact 136 may be disposed in the cell lower insulating layer 190. The cell lower insulating layer 190 may surround the bit line contact 136. The bit line contact 136 may penetrate the barrier layer 150 and be connected to the channel pad 132.

The channel pad 132 may include, for example, a polysilicon doped with impurities such as but not limited to one or more of boron, arsenic, or phosphorus, but example embodiments are not limited thereto. The bit line contact 136 may include, for example, a conductive material such as one or more of tungsten (W), copper (Cu), aluminum (Al), or molybdenum (Mo).

The bit line BL may be disposed in the cell lower insulating layer 190. The cell lower insulating layer 190 may surround the bit line BL. The bit line BL may extend in the second direction D2. The bit line BL may be connected to the channel pad 132 through the bit line contact 136. A cell via 138 may be disposed on the bit line BL. The cell via 138 may connect the bit line BL to the first bonding pad 195. The first bonding pad 195 may be disposed on a lower surface of the cell lower insulating layer 190.

Some gate electrodes 120 among the plurality of gate electrodes 120 may be arranged in a staircase shape. For example, among the plurality of gate electrodes 120, the gate electrodes 120_1 and 120_2 provided as a string select line SSL may be arranged in a staircase shape. In some example embodiments, the gate electrodes 120_1 and 120_2 may have a staircase shape that is symmetrical in a cross-sectional view. For example, the shapes of the gate electrodes 120_1 and 120_2 may form a stair structure that is symmetrical about a virtual line extending in the third direction D3. However, example embodiments are not limited thereto. For example, the shape of the gate electrodes 120_1 and 120_2 may include a single staircase shape.

A cell string contact 176 may be disposed on the gate electrodes 120_1 and 120_2. The cell string contact 176 may penetrate the barrier layer 150 and be connected to the gate electrodes 120_1 and 120_2. A portion of the cell string contact 176 may be surrounded by the air gap AG. The cell string contact 176 may be connected to a cell wiring structure 182. The cell wiring structure 182 may be disposed in the cell lower insulating layer 190.

The word line contact 170 may be disposed over the extension region EXT. The word line contact 170 may extend in the third direction D3. The word line contact 170 may be connected to one gate electrode 120 among the plurality of gate electrodes 120. The word line contact 170 may penetrate other gate electrodes 120 disposed between the one gate electrode 120 to which it is connected and the cell lower insulating layer 190. A word line via 174 may be disposed on the word line contact 170. The word line via 174 may be connected to the first bonding pad 195.

A contact spacer 172 may surround or at least partially surround the word line contact 170. For example, the contact spacer 172 may be disposed on an outer side surface of the word line contact 170. The contact spacer 172 may not be disposed on an upper surface of the word line contact 170. For example, the contact spacer 172 may be disposed between the side surface of the word line contact 170 and the gate electrode 120, and between the side surface of the word line contact 170 and the air gap AG, while not being disposed between an upper surface of the word line contact 170 and the gate electrode 120. By the contact spacer 172, the word line contact 170 and the gate electrode 120 may be spaced apart from each other in the first direction D1 and the second direction D2.

In some example embodiments, the semiconductor memory device may further include a second high-k insulating film HK2 surrounding the word line contact 170. The second high-k insulating film HK2 may be disposed on an outer side surface of the contact spacer 172. The second high-k insulating film HK2 may surround the contact spacer 172. A portion of the second high-k insulating film HK2 may be disposed on the air gap AG, and another portion of the second high-k insulating film HK2 may contact the gate electrode 120.

The support structure 160 may be disposed over the extension region EXT. The support structure 160 may be disposed around the word line contact 170. For example, four support structures 160 may be disposed around one word line contact 170. However, example embodiments are not limited thereto. For example, three support structures 160 may be disposed around one word line contact 170. The support structure 160 may support the plurality of gate electrodes 120 and the word line contact 170, preventing the word line contact 170 from collapsing or falling over.

The support structure 160 may include a vertical portion 160_V extending in the third direction D3 and a horizontal portion 160_H extending in a fourth direction D4. Here, the fourth direction D4 may be parallel to a lower surface of the cell lower insulating layer 190. The vertical portion 160_V of the support structure 160 may be formed in a shape similar to the channel structure CH. The horizontal portion 160_H of the support structure 160 may extend in the first direction D1, the second direction D2, and the fourth direction D4. The horizontal portion 160_H of the support structure 160 may be disposed at the same vertical level as the gate electrode 120. As used herein, “the same vertical level” means being placed at the same height in the third direction D3 from the lower surface of the cell lower insulating layer 190. Here, “the same” may mean substantially the same, including a margin of error in the manufacturing process.

The support structure 160 may include an insulating material. For example, the support structure 160 may include an insulating material belonging to the silicon oxide family. However, example embodiments are not limited thereto.

In some example embodiments, the support structure 160 may further include a third high-k insulating film HK3. The third high-k insulating film HK3 may define an outer side surface of the support structure 160. For example, the third high-k insulating film HK3 may surround the vertical portion 160_V and the horizontal portion 160_H of the support structure 160. The vertical portion 160_V and the horizontal portion 160_H of the support structure 160 may be disposed within the third high-k insulating film HK3. A portion of the third high-k insulating film HK3 may be disposed on the air gap AG, and another portion of the third high-k insulating film HK3 may contact the gate electrode 120.

Each of the first high-k insulating film HK1, the second high-k insulating film HK2, and the third high-k insulating film HK3 may include a high-k material. The high-k material may include, for example, at least one of hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, or lead zinc niobate.

In some example embodiments, each of the first high-k insulating film HK1, the second high-k insulating film HK2, and the third high-k insulating film HK3 may include the same material and/or have the same dielectric constant and/or the same thickness. However, example embodiments are not limited thereto. For example, some of the first high-k insulating film HK1, the second high-k insulating film HK2, and the third high-k insulating film HK3 may include the same material, and each of the first high-k insulating film HK1, the second high-k insulating film HK2, and the third high-k insulating film HK3 may include different materials.

The peripheral circuit structure PERI may include a peripheral circuit substrate 200, a peripheral circuit element 260, and a peripheral circuit wiring structure 280.

The peripheral circuit substrate 200 may include, for example, a semiconductor substrate such as one or more of a silicon substrate, a germanium substrate, or a silicon-germanium substrate. Alternatively or additionally, the peripheral circuit substrate 200 may include, for example, a silicon-on-insulator (SOI) substrate or a germanium-on-insulator (GOI) substrate.

The peripheral circuit element 260 may be formed on the peripheral circuit substrate 200. The peripheral circuit element 260 may constitute a peripheral circuit that controls the operation of the semiconductor memory device. As used herein, a surface of the peripheral circuit substrate 200 on which the peripheral circuit element 260 is disposed may be referred to as a front side of the peripheral circuit substrate 200. Conversely, a surface of the peripheral circuit substrate 200 opposite the front side may be referred to as a back side of the peripheral circuit substrate 200.

The peripheral circuit element 260 may include, for example, a transistor such as but not limited to a planar transistor, but is not limited thereto. For example, the peripheral circuit element 260 may include various active elements such as a transistor and/or a diode, as well as various passive elements such as one or more of capacitors, resistors, or inductors. An orientation of the peripheral circuit element 260 may be the same as illustrated, or may be different than as illustrated.

The peripheral circuit wiring structure 280 may be formed on the peripheral circuit element 260. For example, a peripheral circuit insulating film 290 may be formed on the front side of the peripheral circuit substrate 200, and the peripheral circuit wiring structure 280 may be formed in the peripheral circuit insulating film 290. The peripheral circuit wiring structure 280 may be electrically connected to the peripheral circuit element 260. The number of layers and/or the arrangement of and/or the thicknesses of the peripheral circuit wiring structure 280 shown are merely illustrative and are not limiting.

In some example embodiments, the cell structure CELL may be stacked on the peripheral circuit structure PERI. For example, the cell structure CELL may be stacked on the peripheral circuit insulating film 290.

A semiconductor memory device according to some example embodiments may have a chip-to-chip (C2C) structure. The C2C structure means that an upper chip, which includes the cell structure CELL, is fabricated on a first wafer, and a lower chip, which includes the peripheral circuit structure PERI on another wafer (e.g., the peripheral circuit substrate 200) different from the first wafer, is fabricated, and then the upper chip and the lower chip are connected to each other by a bonding method.

In some example embodiments, the bonding method may mean a method of electrically connecting a first bonding pad 195 formed on the uppermost metal layer of the upper chip and a second bonding pad 295 formed on the uppermost metal layer of the lower chip. For example, when the first bonding pad 195 and the second bonding pad 295 are formed of copper (Cu), the bonding method may be or may include a Cu—Cu bonding method. However, this is merely an example, and the first bonding pad 195 and the second bonding pad 295 may also or alternatively be formed of other various metals such as aluminum (Al) or tungsten (W).

By bonding the first bonding pad 195 and the second bonding pad 295, the cell wiring structure 182 and the cell via 138 may be connected to the peripheral circuit wiring structure 280. Thus, the bit line BL and/or each gate electrode 120 may be electrically connected to the peripheral circuit element 260.

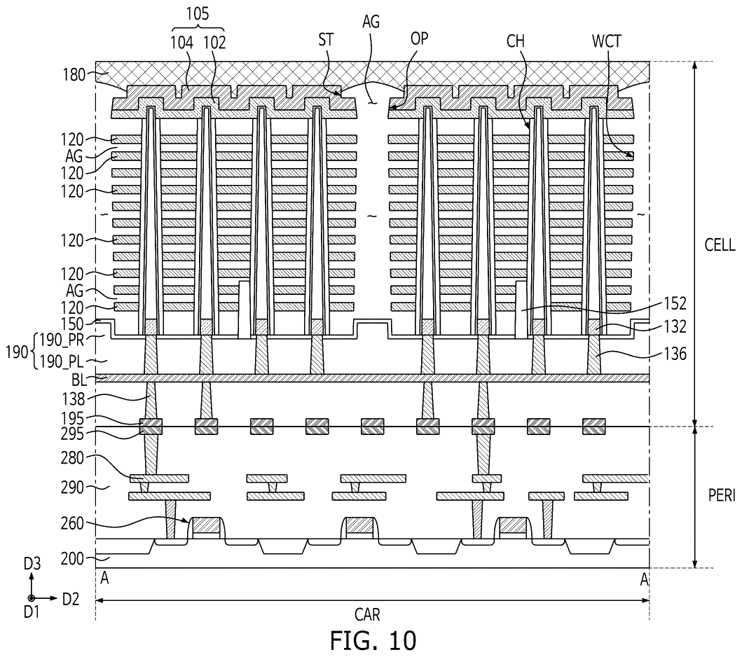

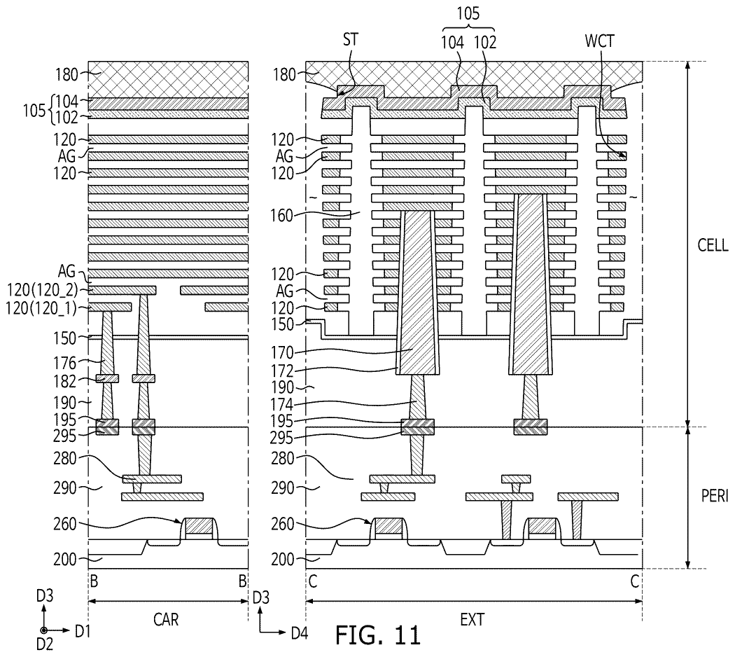

FIGS. 10 and 11 are diagrams illustrating a semiconductor memory device according to some example embodiments. For convenience of explanation, descriptions focus on configurations different from those described in FIGS. 1-9.

Referring to FIGS. 10 and 11, in a semiconductor memory device according to some embodiments, the source plate structure 105 may include a step ST.

The step ST of the source plate structure 105 may be disposed on the conductive layer 104. For example, the step ST of the source plate structure 105 may be formed on the conductive layer 104 disposed over the opening OP. The step ST of the source plate structure 105 may have a staircase shape.

In some example embodiments, the air gap AG may be disposed on the gate isolation trench WCT, the opening OP, and the step ST of the source plate structure 105. For example, the air gap AG may be disposed on a remainder of the step ST of the source plate structure 105 in which the cell upper insulating layer 180 is disposed.

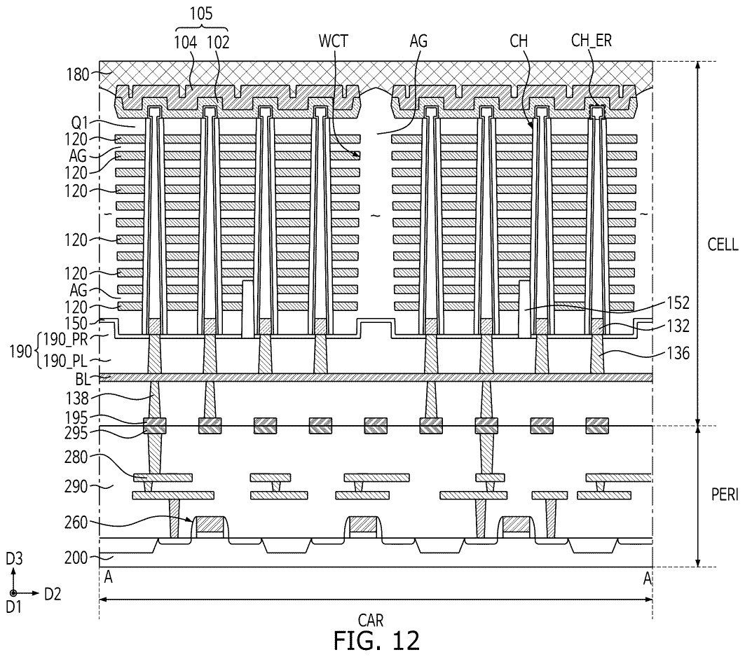

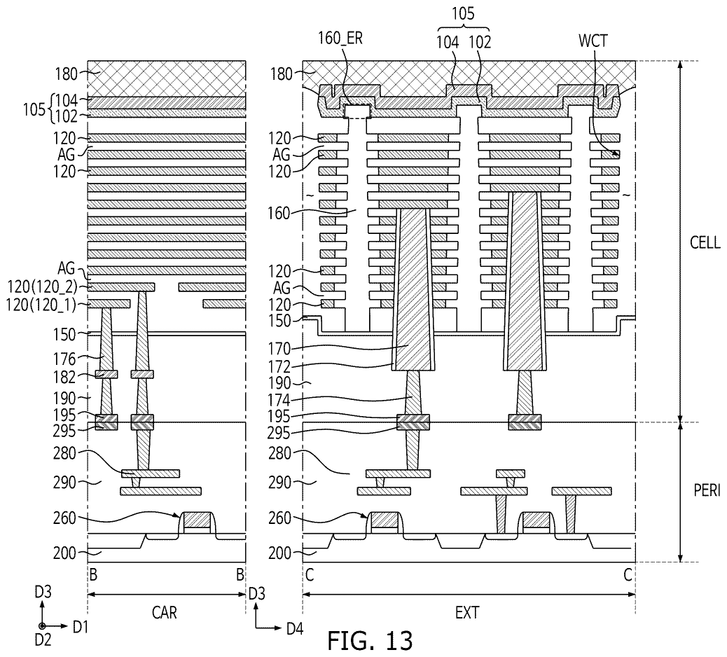

FIGS. 12 and 13 are diagrams illustrating a semiconductor memory device according to some example embodiments. For convenience of explanation, descriptions focus on configurations different from those described in FIGS. 1-9.

Referring to FIGS. 12 and 13, in a semiconductor memory device according to some embodiments, the cell structure CH may include a first width expansion region CH_ER.

The first width expansion region CH_ER may be disposed at one end of the channel structure CH. The first width expansion region CH_ER may be disposed within the source plate structure 105. For example, the semiconductor layer 102 may surround the first width expansion region CH_ER. The first width expansion region CH_ER may be disposed at one end of the cell structure CH, and may be defined as a portion whose width in the first direction D1 and the second direction D2 changes abruptly. For example, a step may define a boundary between the first width expansion region CH_ER of the channel structure CH and the remaining region.

The support structure 160 may include a second width expansion region 160_ER. The second width expansion region 160_ER may be disposed at one end of the support structure 160. The second width expansion region 160_ER may be disposed within the source plate structure 105. For example, the semiconductor layer 102 may surround the second width expansion region 160_ER. The second width expansion region 160_ER may be disposed at one end of the support structure 160, and may be defined as a portion whose width in the first direction D1 and the second direction D2 changes abruptly. For example, a step may define a boundary between the second width expansion region 160_ER among the vertical portion of the dummy support structure 160 and the remaining region.

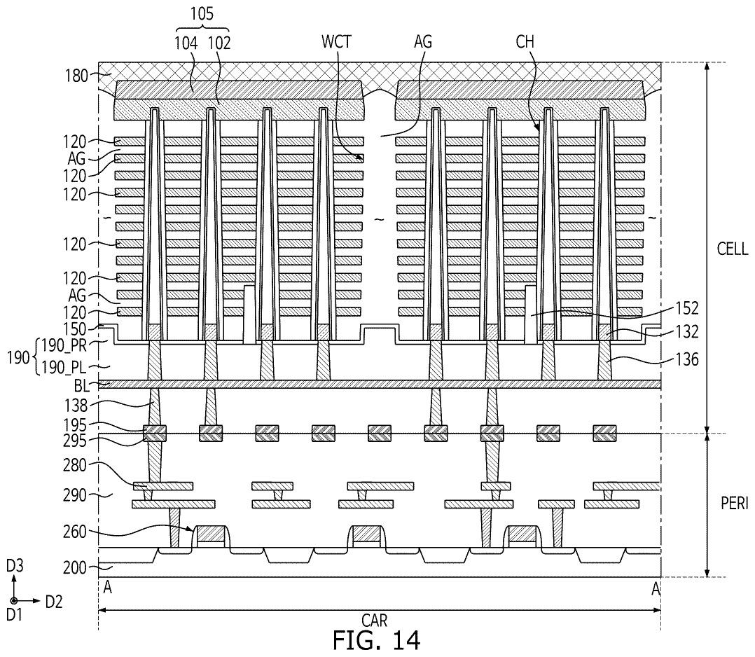

FIG. 14 is a diagram illustrating a semiconductor memory device according to some example embodiments. For convenience of explanation, descriptions focus on configurations different from those described in FIGS. 1-9.

Referring to FIG. 14, in a semiconductor memory device according to some embodiments, the source plate structure 105 may include a plate shape.

The source plate structure 105 may include the semiconductor layer 102 and the conductive layer 104. One end of the channel structure CH may penetrate a lower surface of the semiconductor layer 102. An upper surface of the semiconductor layer 102 may have a plane parallel to the first direction D1 and the second direction D2. The conductive layer 104 may be disposed on the semiconductor layer 102. A lower surface and an upper surface of the conductive layer 104 may each have a plane parallel to the first direction D1 and the second direction D2.

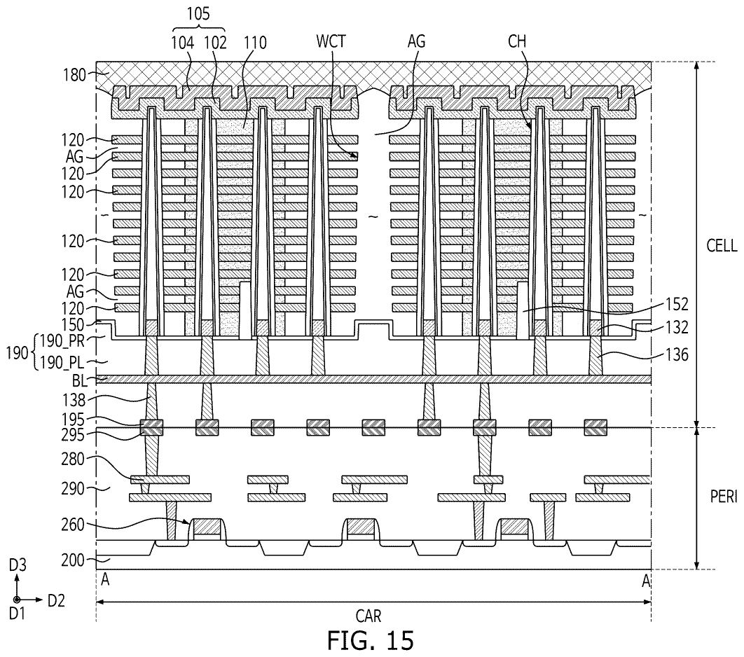

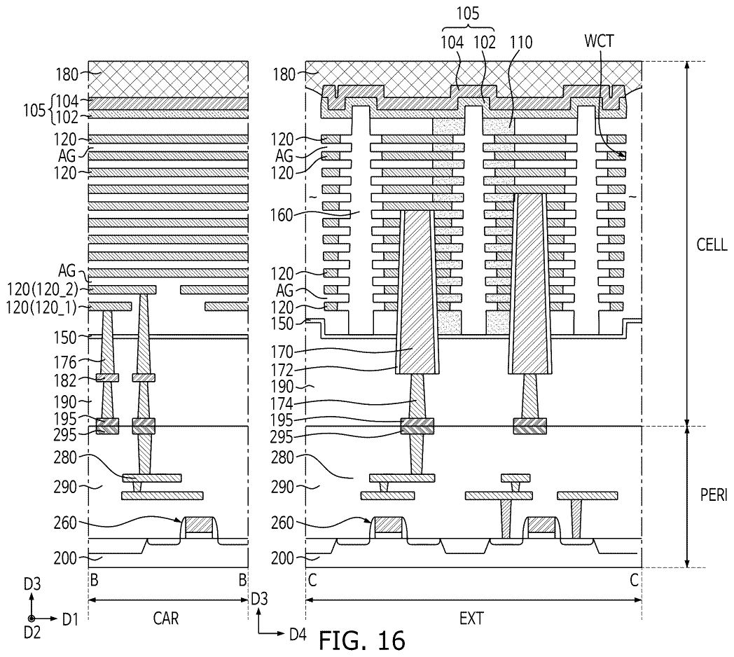

FIGS. 15 and 16 are diagrams illustrating a semiconductor memory device according to some example embodiments. For convenience of explanation, descriptions focus on configurations different from those described in FIGS. 1-9.

Referring to FIGS. 15 and 16, in some example embodiments, the semiconductor memory device may further include a mold insulating layer 110.

The mold insulating layer 110 may be disposed between the plurality of gate electrodes 120, between the gate electrode 120 and the source plate structure 105, and between the plurality of gate electrodes 120 and the barrier layer 150. The mold insulating layer 110 may be disposed on the channel structure CH. For example, the mold insulating layer 110 may be disposed around the channel structure CH that is spaced far away from the gate isolation trench WCT. The mold insulating layer 110 may be disposed on the support structure 160. For example, the mold insulating layer 110 may be disposed around the support structure 160 that is spaced far away from the gate isolation trench WCT.

In some example embodiments, the mold insulating layer 110 may be or may include (or be included in) a remaining portion that is not removed by an etching process. Before forming the air gap AG among the plurality of gate electrodes 120, the plurality of gate electrodes 120 and the plurality of mold insulating layers 110 may be alternately stacked. To form the air gap AG between the plurality of gate electrodes 120, the mold insulating layer 110 may be removed. In that process, the mold insulating layer 110 adjacent to the gate isolation trench WCT may be removed, and the mold insulating layer 110 spaced away from the gate isolation trench WCT may remain without being removed.

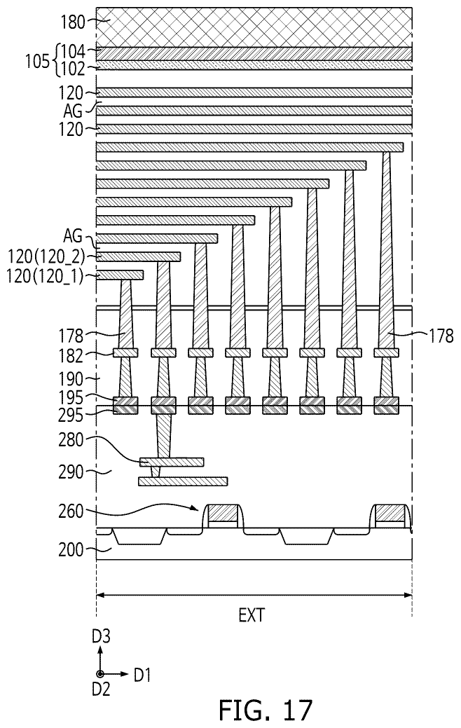

FIG. 17 is a diagram illustrating a semiconductor memory device according to some example embodiments. For convenience of explanation, descriptions focus on configurations different from those described in FIGS. 1-9.

Referring to FIG. 17, in a semiconductor memory device according to some embodiments, the plurality of gate electrodes 120 may have a staircase shape on the extension region EXT. The plurality of gate electrodes 120 may extend in the first direction D1 with different lengths, respectively, forming a stepped structure. Due to the stepped structure, a specific gate electrode 120 may include an end portion exposed by a gate electrode 120 disposed below that specific gate electrode 120. A word line contact 178 may be formed on the end portion of the gate electrode 120. The word line contact 178 may be connected to the gate electrode 120.

The air gap AG may be disposed between the plurality of gate electrodes 120. The air gap AG may surround a portion of the word line contact 178. For example, the air gap AG may surround the word line contact 178 that is disposed over the barrier layer 150 among the word line contacts 178.

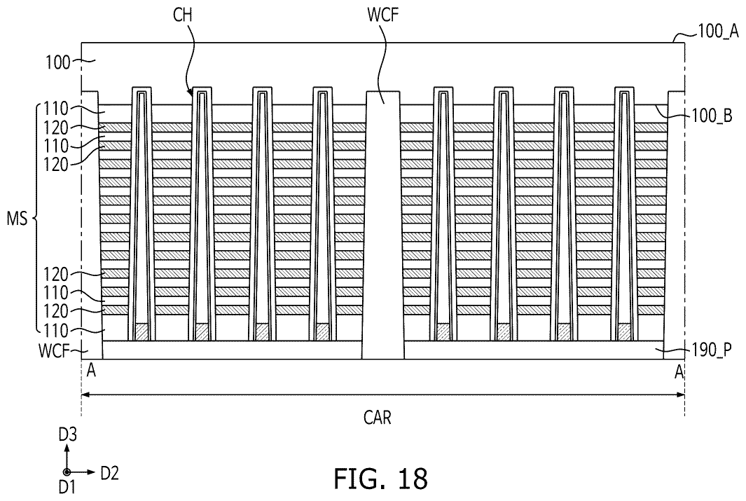

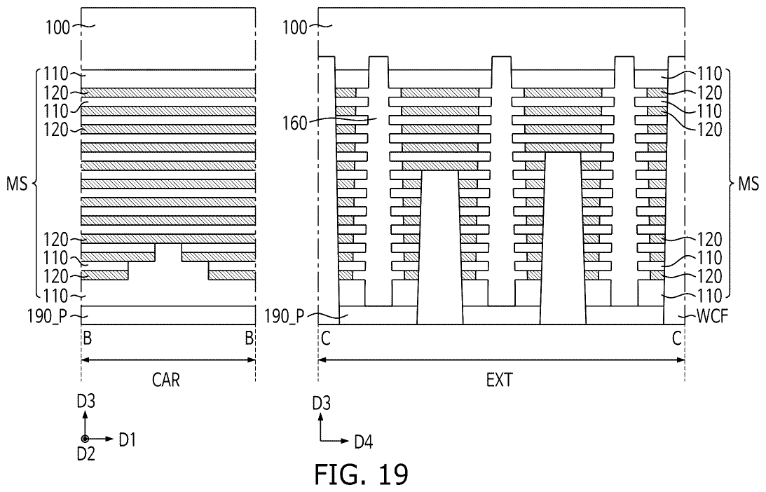

FIGS. 18-33 are diagrams illustrating a method for manufacturing a semiconductor memory device according to some example embodiments. For reference, FIGS. 18, 20, 22, 24, 26, 28, 30, and 32 may each correspond to the cross-sectional view along line A-A of FIG. 1. FIGS. 19, 21, 23, 25, 27, 29, 31, and 33 may each correspond to the cross-sectional view along lines B-B and C-C of FIG. 1. For convenience of explanation, the same configurations described in FIGS. 1-9 are omitted or briefly explained.

Referring to FIGS. 18 and 19, in a method of manufacturing a semiconductor memory device according to some example embodiments, a mold structure MS, a channel structure CH, a gate isolation structure WCF, a pre-insulating layer 190_P, and a support structure 160 may be formed on a cell substrate 100. The mold structure MS, the channel structure CH, the gate isolation structure WCF, the pre-insulating layer 190_P, and the support structure 160 may be formed with one or more processes, including one or more of a chemical vapor deposition (CVD) process, a physical vapor deposition (PVD) process, a photolithography process, a chemical mechanical planarization process, an etching process such as a dry etching process and/or a wet etching process, and an implantation process; example embodiments are not limited thereto.

The cell substrate 100 may include, for example, a semiconductor substrate such as a silicon substrate, a germanium substrate, or a silicon-germanium substrate. Alternatively or additionally, the cell substrate 100 may include, for example, a silicon-on-insulator (SOI) substrate or a germanium-on-insulator (GOI) substrate. In some example embodiments, the cell substrate 100 may include polysilicon (poly Si).

The cell substrate 100 may include a first surface 100_A and a second surface 100_B facing the first surface 100_A. The second surface 100_B of the cell substrate 100 may be a surface on which the mold structure MS and the channel structure CH are disposed. The first surface 100_A of the cell substrate 100 may be referred to as a back side of the cell substrate 100. The second surface 100_B of the cell substrate 100 may be referred to as a front side of the cell substrate 100.

The mold structure MS may be disposed on the second surface 100_B of the cell substrate 100. The mold structure MS may include a plurality of mold insulating layers 110 and a plurality of gate electrodes 120 alternately stacked in the third direction D3. Each mold insulating layer 110 and each gate electrode 120 may have a layer structure extending parallel to the first surface 100_A of the cell substrate 100. A thickness of and/or a material composition of each of the gate electrodes 120 and/or the insulating layer 110 may be the same; alternatively, a thickness of and/or a material composition of at least one of the gate electrodes 120 and/or the insulating layers 110 may be different than others of the gate electrodes 120 and/or the insulating layers 110. The mold structure MS may be formed in deposition process such as but not limited to an atomic layer deposition (ALD) process; example embodiments are not limited thereto.

The channel structure CH may be disposed on the cell array region CAR. The channel structure CH may extend in the third direction D3 and may penetrate the mold structure MS. One end of the channel structure CH may be disposed in the cell substrate 100. In some example embodiments, before forming the channel structure CH, a first high-k insulating film (for example, HK1 of FIG. 5) may be formed. For example, a channel hole penetrating the mold structure MS may be formed, and the first high-k insulating film HK1 may be formed in the channel hole. Then, the information storage film 140, the semiconductor pattern 148, and the filling pattern 149 may be sequentially formed on the first high-k insulating film HK1.

The gate isolation structure WCF may penetrate the mold structure MS. The gate isolation structure WCF may extend in the first direction D1 and the third direction D3. One end of the gate isolation structure WCF may be disposed in the cell substrate 100.

The support structure 160 may be disposed over the extension region EXT. The support structure 160 may penetrate the mold structure MS. In some example embodiments, before forming the support structure 160, a third high-k insulating film (for example, HK3 of FIG. 9) may be formed. For example, a support structure hole for forming the support structure 160 may be formed. The support structure hole may include a vertical portion penetrating the mold structure MS and a horizontal portion disposed between the gate electrodes 120. The third high-k insulating film HK3 may be formed in the support structure hole. Then, the support structure 160 may be formed on the third high-k insulating film HK3.

The pre-insulating layer 190_P may be disposed under the channel structure CH and the mold structure MS. The pre-insulating layer 190_P may be disposed between adjacent gate isolation structures WCF.

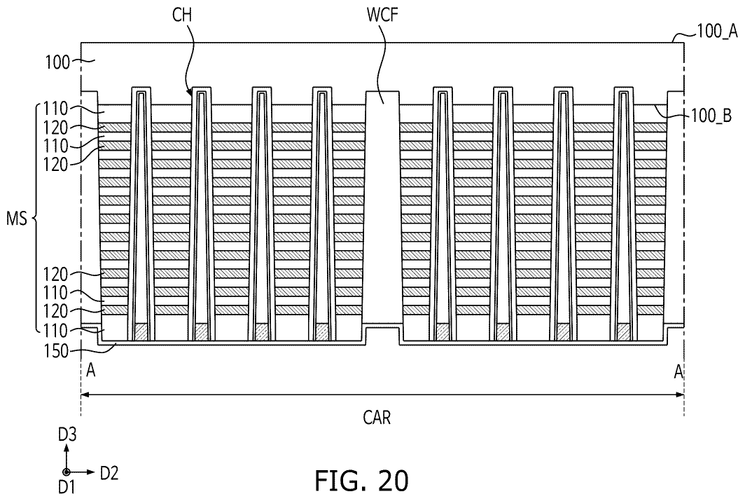

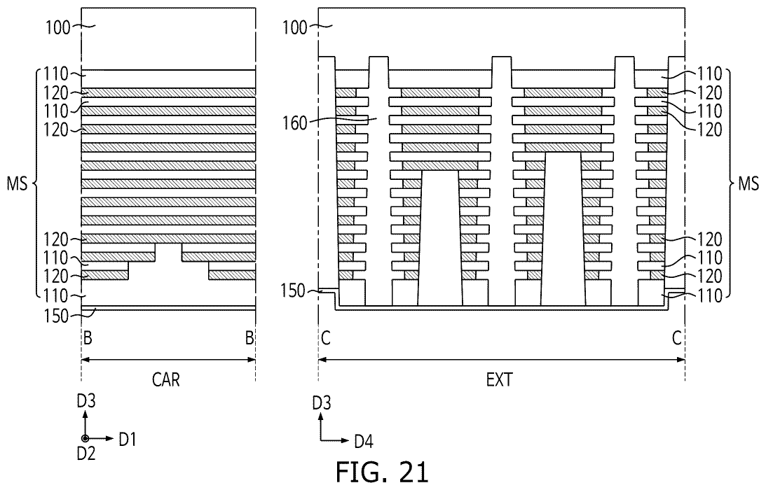

Referring to FIGS. 20 and 21, the barrier layer 150 may be formed on the gate isolation structure WCF and the channel structure CH.

Specifically, a portion of the pre-insulating layer (for example, 190_P of FIGS. 19 and 20) and a portion of the gate isolation structure WCF may be removed, e.g. with an etch-back process and/or a CMP process, exposing lower surfaces of the channel structure CH, the mold structure MS, and the gate isolation structure WCF. Because a portion of the gate isolation structure WCF is removed, a lower surface of the gate isolation structure WCF may be disposed at a higher vertical level than a lower surface of the channel structure CH. For example, a distance from the first surface 100_A of the cell substrate 100 to the lower surface of the gate isolation structure WCF may be smaller than a distance from the first surface 100_A of the cell substrate 100 to the lower surface of the channel structure CH.

Subsequently, the barrier layer 150 may be formed along the lower surface of the gate isolation structure WCF, the lower surface of the mold structure MS, and the lower surface of the channel structure CH. The barrier layer 150 may include a material having an etching selectivity with respect to the mold insulating layer 110.

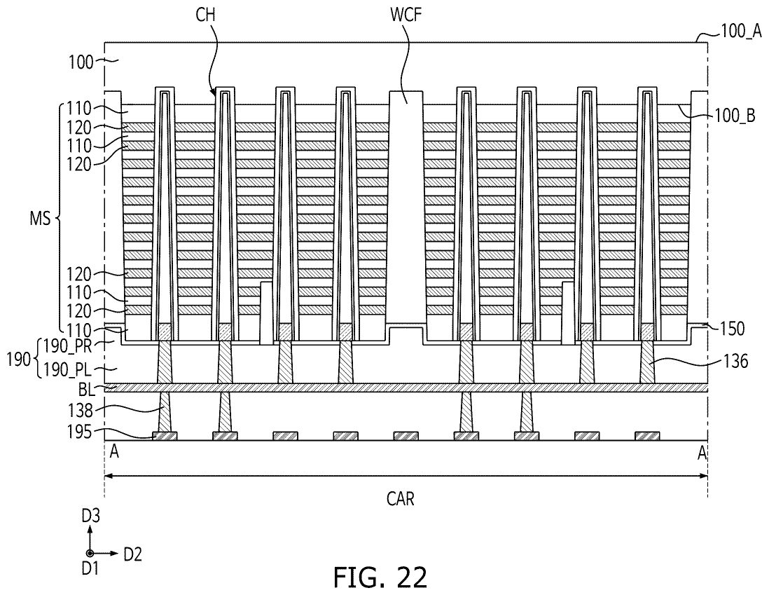

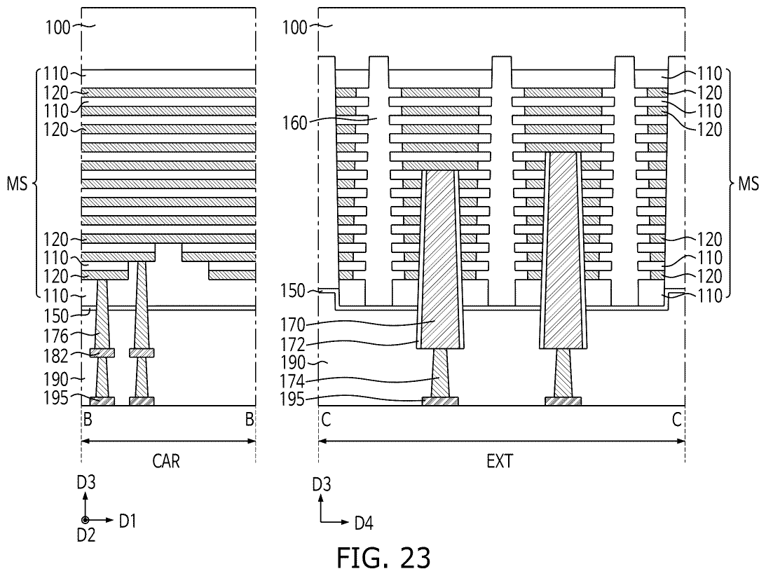

Referring to FIGS. 22 and 23, a word line contact 170, a contact spacer 172, a word line via 174, a bit line contact 136, a bit line BL, a cell via 138, a first bonding pad 195, a cell string contact 176, a cell wiring structure 182, and the cell lower insulating layer 190 may be formed, e.g., with a deposition process and/or a photolithography process and/or an etching process.

In some example embodiments, before forming the word line contact 170, a second high-k insulating film (for example, HK2 of FIG. 9) may be formed. For example, a word line contact hole for forming the word line contact 170 may be formed. The word line contact hole may penetrate a portion of the mold structure MS. The second high-k insulating film HK2 may be formed in the word line contact hole. Then, the contact spacer 172 and the word line contact 170 may be sequentially formed on the second high-k insulating film HK2.

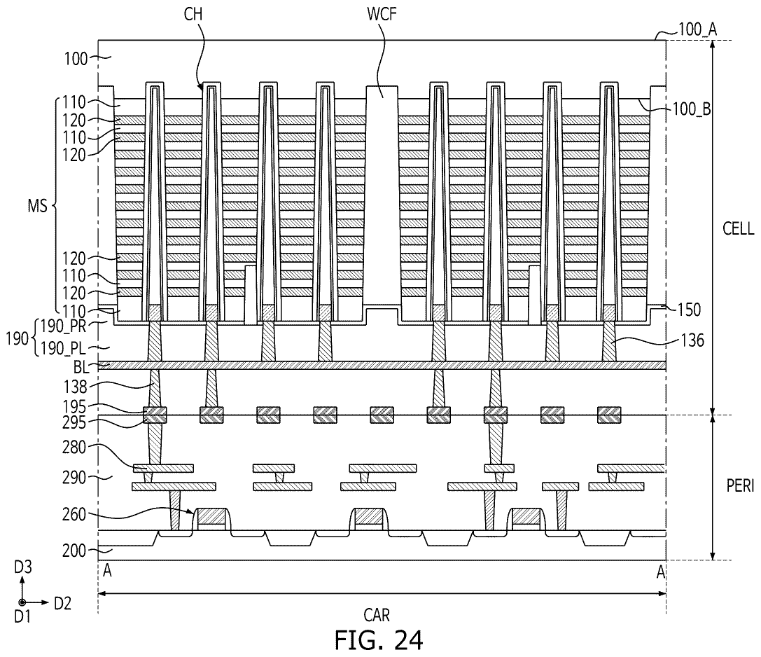

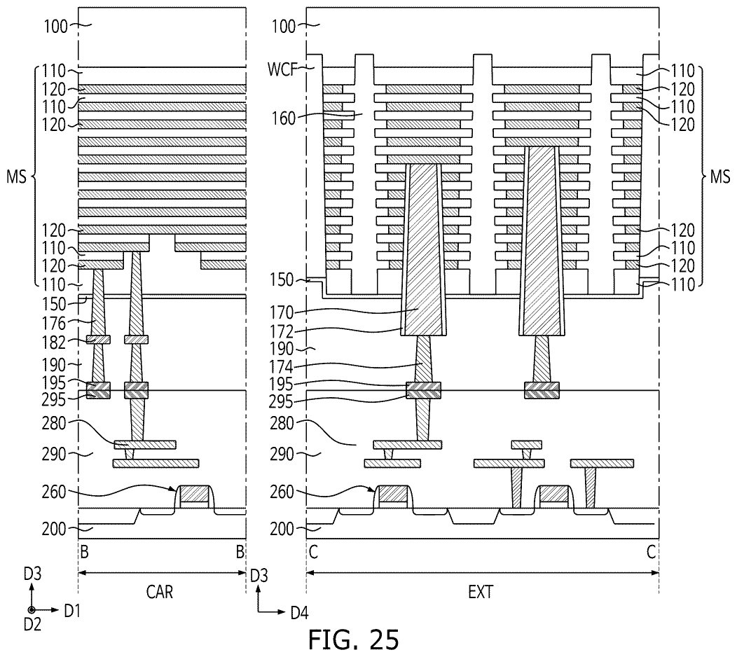

Referring to FIGS. 24 and 25, the peripheral circuit structure PERI and the cell structure CELL may be coupled. The peripheral circuit structure PERI may be formed on a wafer different from the cell structure CELL. The second bonding pad 295 of the peripheral circuit structure PERI and the first bonding pad 195 of the cell structure CELL may be bonded, e.g., with a wafer-to-wafer (W2W) bonding process.

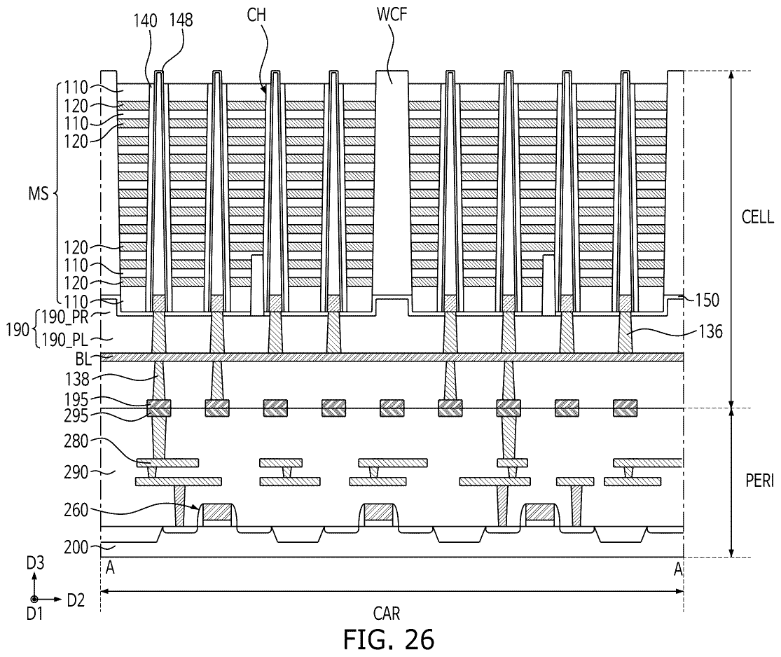

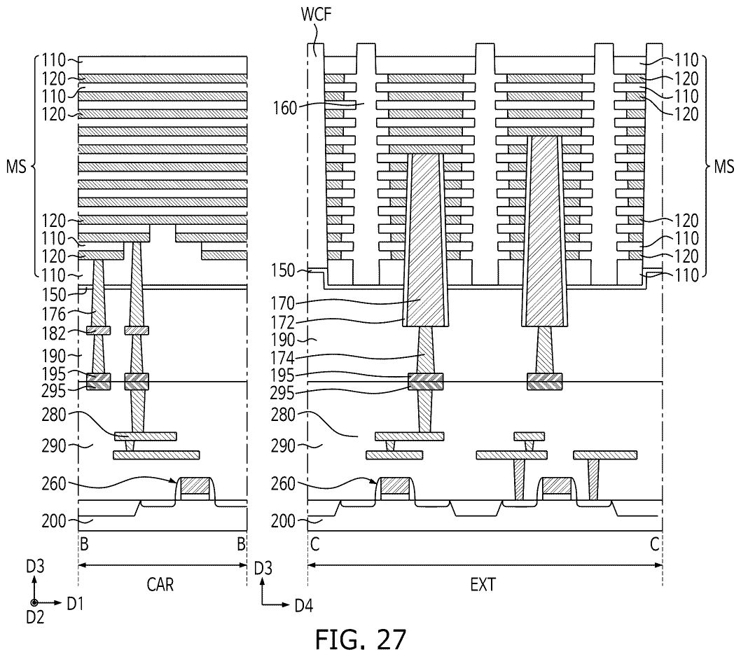

Referring to FIGS. 26 and 27, the cell substrate (for example, 100 of FIGS. 22 and 23) and a portion of the channel structure CH may be removed.

Specifically, the cell substrate 100 may be removed to expose an upper portion of the channel structure CH, an upper portion of the gate isolation structure WCF, an upper portion of the support structure 160, and the upper surface of the mold structure MS. Then, a portion of the channel structure CH may be removed. For example, a portion of the information storage film 140 may be removed to expose the semiconductor pattern 148 of the channel structure CH.

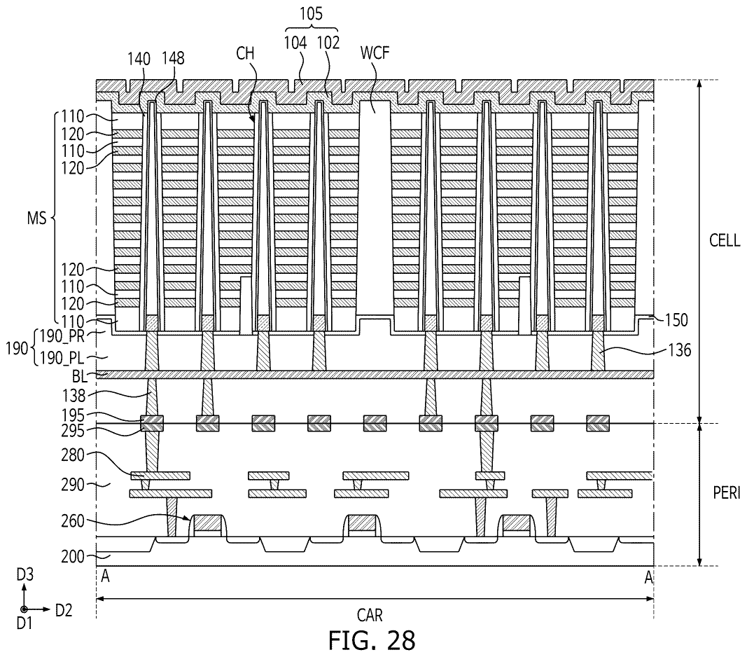

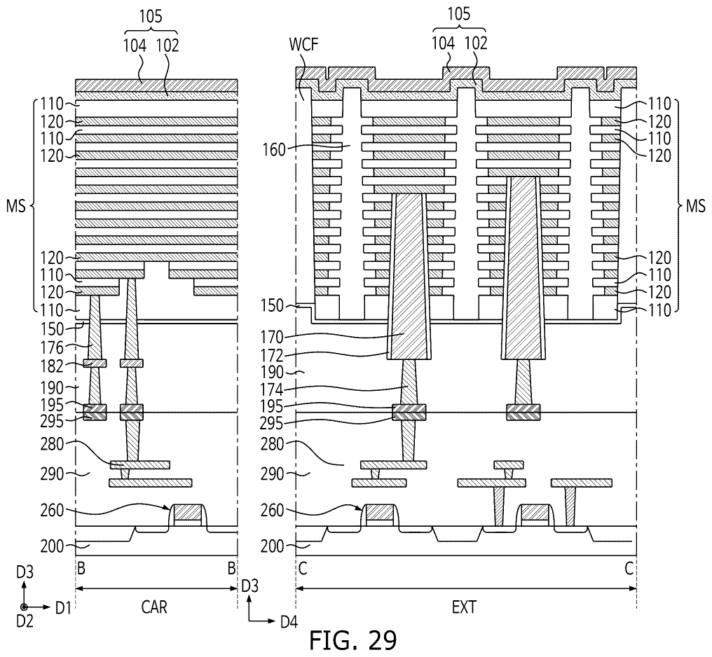

Referring to FIGS. 28 and 29, the source plate structure 105 may be formed on the channel structure CH, the support structure 160, the mold structure MS, and the gate isolation structure WCF.

The source plate structure 105 may include a semiconductor layer 102 and a conductive layer 104. The semiconductor layer 102 may cover the upper portion of the channel structure CH, the upper portion of the support structure 160, the upper surface of the mold structure MS, and the upper portion of the gate isolation structure WCF. For example, the semiconductor layer 102 may contact the semiconductor pattern 148 of the channel structure CH. The semiconductor layer 102 may contact the topmost mold insulating layer 110 in the mold structure MS. The conductive layer 104 may be formed on the semiconductor layer 102. The conductive layer 104 may extend along the profile of the semiconductor layer 102.

Referring to FIGS. 30 and 31, the opening OP may be formed on the source plate structure 105, and the gate isolation structure (for example, WCF of FIGS. 28 and 29) may be removed.

Specifically, an etching process, e.g., a wet etching process including a chemical such as but not limited to hydrogen fluoride (HF) and/or nitric acid may be performed on the source plate structure 105. A portion of the source plate structure 105 may be removed by the etching process, and the opening OP may be formed. The opening OP may expose the gate isolation structure WCF. The depth of the opening OP formed by the etching process may vary.

Subsequently, an etching process, e.g., a wet etching process including a chemical such as but not limited to hydrogen fluoride (HF) and/or nitric acid may be performed on the opening OP to remove the gate isolation structure WCF, and the gate isolation trench WCT may be formed. The gate isolation trench WCT may be defined as the trench remaining after the gate isolation structure WCF is removed. The gate isolation trench WCT may expose a side surface of the mold structure MS and a portion of the barrier layer 150.

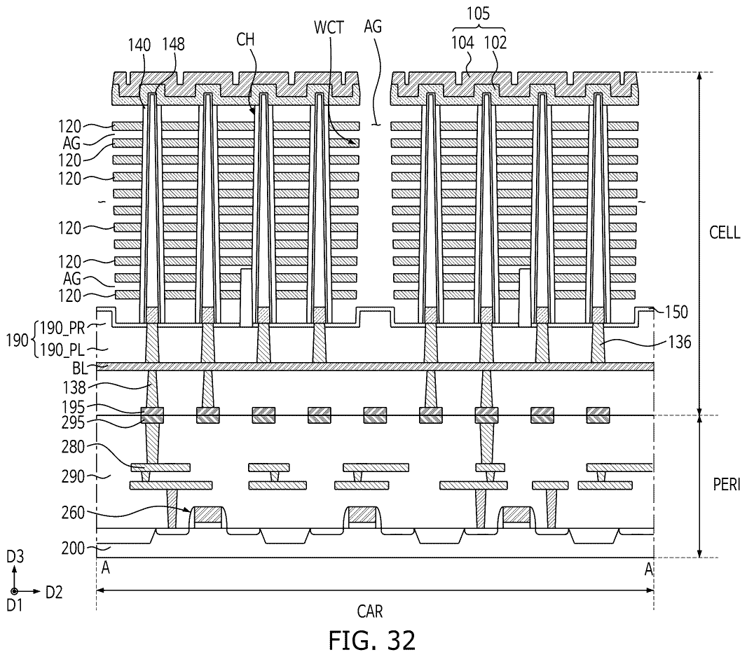

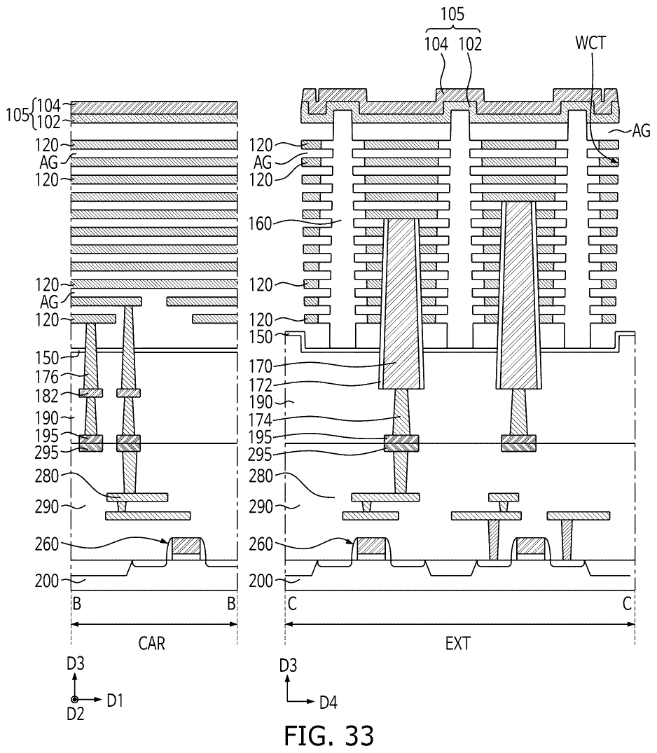

Referring to FIGS. 32 and 33, the mold insulating layer (for example, 110 of FIGS. 30 and 31) may be removed, and the air gap AG may be formed.

Specifically, an etching process, e.g., a wet etching process including a chemical such as but not limited to hydrogen fluoride (HF) and/or nitric acid may be performed on the mold structure (for example, MS of FIGS. 30 and 31) exposed by the gate isolation trench WCT. In the etching process, an etchant having an etching selectivity with respect to the mold insulating layer (for example, 110 of FIGS. 30 and 31) may be used. As a result, the mold insulating layer 110 of the mold structure MS may be removed, and the air gap AG may be formed. The air gap AG may fill the space remaining after removing the mold insulating layer 110 and an interior of the gate isolation trench WCT. The air gap AG may be formed of or include clean, dry air (CDA) and/or nitrogen; example embodiments are not limited thereto.

The barrier layer 150 may protect the cell lower insulating layer 190 during the etching process that removes the mold insulating layer 110. For example, when the mold insulating layer 110 is removed, the barrier layer 150 may not be removed, and may not expose the cell lower insulating layer 190. As a result, the cell lower insulating layer 190 may not be removed.

In some example embodiments, the channel structure CH may include a first high-k insulating film (for example, HK1 of FIG. 5). The first high-k insulating film HK1 may protect the channel structure CH during the etching process that removes the mold insulating layer 110. Because of the first high-k insulating film HK1, the channel structure CH may not be removed in the etching process.

In some example embodiments, a second high-k insulating film (for example, HK2 of FIG. 9) may be disposed on the outer side surface of the contact spacer 172. The second high-k insulating film HK2 may protect the contact spacer 172 during the etching process that removes the mold insulating layer 110. Because of the second high-k insulating film HK2, the contact spacer 172 may not be removed in the etching process.

In some example embodiments, a third high-k insulating film (for example, HK3 of FIG. 9) may be disposed on the outer side surface of the support structure 160. The third high-k insulating film HK3 may protect the support structure 160 during the etching process that removes the mold insulating layer 110. Because of the third high-k insulating film, the support structure 160 may not be removed.

Referring to FIGS. 32 and 33, the cell upper insulating layer 180 may be formed on the source plate structure 105. The cell upper insulating layer 180 may cover the opening OP of the source plate structure 105. By means of the cell upper insulating layer 180, the air gap AG, disposed between the plurality of gate electrodes 120 and in the gate isolation trench WCT, may be blocked from the outside.

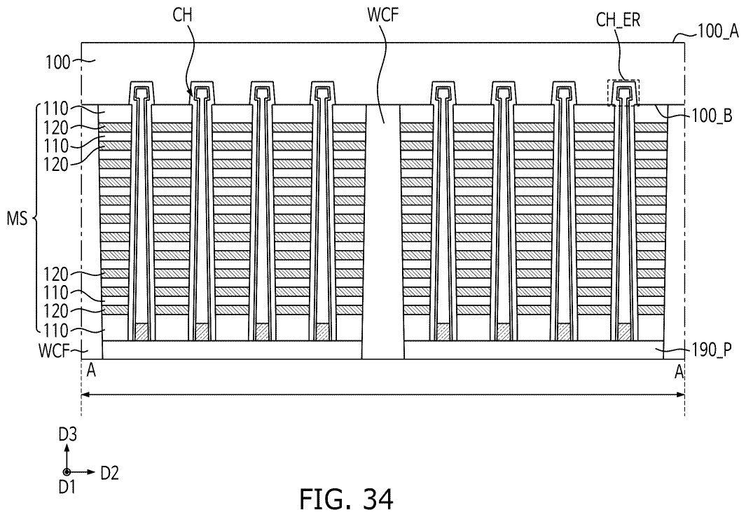

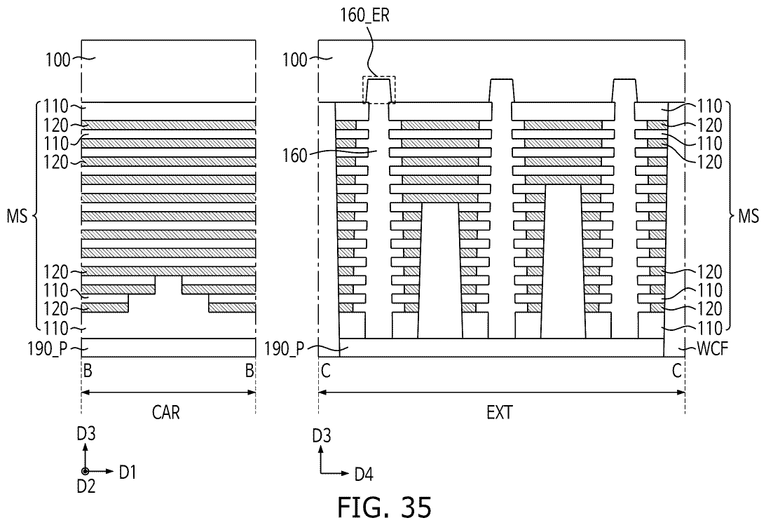

FIGS. 34 and 35 are diagrams illustrating a method of manufacturing a semiconductor memory device according to some example embodiments. For reference, FIGS. 34 and 35 may each correspond to FIGS. 18 and 19. For convenience of explanation, the same configurations described in FIGS. 18-33 are omitted or briefly explained.

Referring to FIGS. 34 and 35, in a method of manufacturing a semiconductor memory device according to some example embodiments, a mold structure MS, a channel structure CH, a gate isolation structure WCF, a pre-insulating layer 190_P, and a support structure 160 may be formed on a cell substrate 100.

According to some example embodiments, a method of manufacturing a semiconductor memory device may include forming a mold structure MS, a channel structure CH, a gate isolation structure WCF, a pre-insulating layer 190_P, and a support structure 160 on the cell substrate 100.

In some example embodiments, the channel structure CH may include a first width expansion region CH_ER. The first width expansion region CH_ER may be disposed at one end of the channel structure CH. The first width expansion region CH_ER may be disposed in the cell substrate 100. The first width expansion region CH_ER may be formed by a first etch stop film. For example, a first etch stop film may be formed in the cell substrate 100, a channel hole for forming the channel structure CH may be formed in the first etch stop film, and then the first etch stop film may be removed, and the channel structure CH may be formed inside the channel hole. The portion from which the first etch stop film is removed may be where the first width expansion region CH_ER is disposed.

The support structure 160 may include a second width expansion region 160_ER. The second width expansion region 160_ER may be disposed at one end of the support structure 160. The second width expansion region 160_ER may be disposed in the cell substrate 100. The second width expansion region 160_ER may be formed by a second etch stop film. For example, a second etch stop film may be formed in the cell substrate 100, a support structure hole for forming the support structure 160 may be formed in the second etch stop film, and then the second etch stop film may be removed, and the support structure 160 may be formed in the support structure hole. The portion from which the second etch stop film is removed may be where the second width expansion region 160_ER is disposed.

In some example embodiments, an upper surface of the gate isolation structure WCF may be disposed at a lower vertical level than an upper surface of the channel structure CH. For example, the distance from the first surface 100_A of the cell substrate 100 to the upper surface of the gate isolation structure WCF may be greater than the distance from the first surface 100_A of the cell substrate 100 to the upper surface of the channel structure CH. Although the upper surface of the gate isolation structure WCF is illustrated as being disposed at the same vertical level as an upper surface of the mold structure MS, example embodiments are not limited thereto. For example, the upper surface of the gate isolation structure WCF may be disposed at a different vertical level from the upper surface of the mold structure MS.

The upper surface of the gate isolation structure WCF may be disposed at a lower vertical level than an upper surface of the support structure 160. For example, the distance from the first surface 100_A of the cell substrate 100 to the upper surface of the gate isolation structure WCF may be greater than the distance from the first surface 100_A of the cell substrate 100 to the upper surface of the support structure 160.

Subsequently, the same manufacturing processes described in FIGS. 20-33 may be performed. As a result, the semiconductor memory device described in FIGS. 10 and 11 may be formed. For example, the source plate structure 105 may include the step ST.

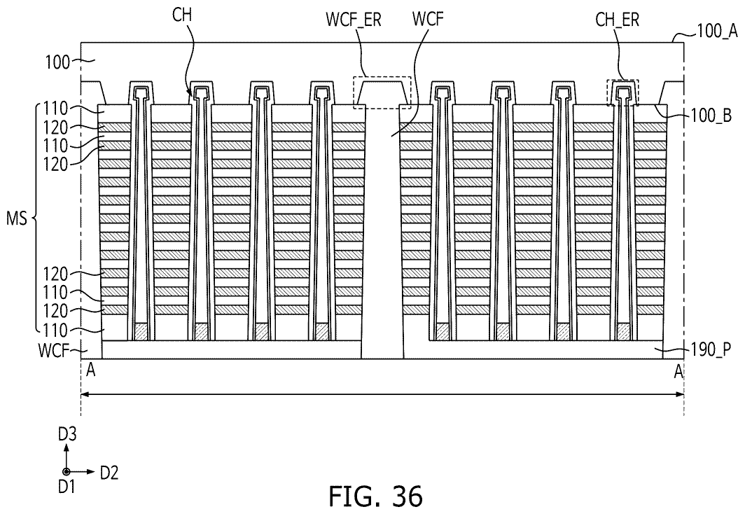

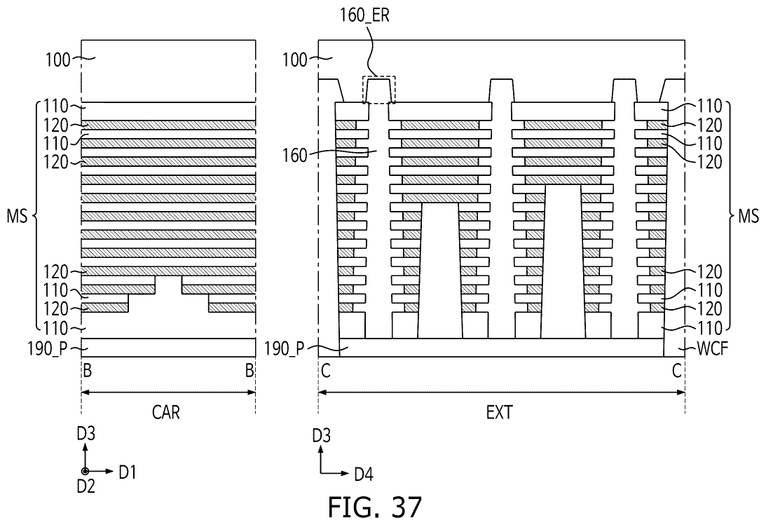

FIGS. 36 and 37 are diagrams illustrating a method of manufacturing a semiconductor memory device according to some example embodiments. For reference, FIGS. 36 and 37 may each correspond to FIGS. 18 and 19. For convenience of explanation, the same configurations described in FIGS. 18-35 are omitted or briefly explained.

Referring to FIGS. 36 and 37, in a method of manufacturing a semiconductor memory device according to some example embodiments, a mold structure MS, a channel structure CH, a gate isolation structure WCF, a pre-insulating layer 190_P, and a support structure 160 may be formed on a cell substrate 100.

In some example embodiments, the channel structure CH may include a first width expansion region CH_ER. The first width expansion region CH_ER may be disposed at one end of the channel structure CH. The first width expansion region CH_ER may be disposed in the cell substrate 100. The support structure 160 may include a second width expansion region 160_ER. The second width expansion region 160_ER may be disposed at one end of the support structure 160. The second width expansion region 160_ER may be disposed in the cell substrate 100.

The gate isolation structure WCF may include a third width expansion region WCF_ER. The third width expansion region WCF_ER may be disposed at one end of the gate isolation structure WCF. The third width expansion region WCF_ER may be disposed in the cell substrate 100. The third width expansion region WCF_ER may be formed by a third etch stop film. For example, the third etch stop film may be formed in the cell substrate 100, and a gate isolation structure trench for forming the gate isolation structure WCF may be formed in the third etch stop film. Then, the third etch stop film may be removed, and the gate isolation structure WCF may be formed in the gate isolation structure trench. The portion from which the third etch stop film is removed may be where the third width expansion region WCF_ER is disposed.

In some example embodiments, the upper surface of the channel structure CH and the upper surface of the gate isolation structure WCF may be disposed at the same vertical level. For example, the distance from the first surface 100_A of the cell substrate 100 to the upper surface of the channel structure CH may be the same as the distance from the first surface 100_A of the cell substrate 100 to the upper surface of the gate isolation structure WCF. However, example embodiments are not limited thereto.

In some example embodiments, the upper surface of the support structure 160 and the upper surface of the gate isolation structure WCF may be disposed at the same vertical level. For example, the distance from the first surface 100_A of the cell substrate 100 to the upper surface of the support structure 160 may be the same as the distance from the first surface 100_A of the cell substrate 100 to the upper surface of the gate isolation structure WCF. However, example embodiments are not limited thereto.

Subsequently, the same manufacturing processes described in FIGS. 20-33 may be performed. As a result, the semiconductor memory device described in FIGS. 12 and 13 may be formed.

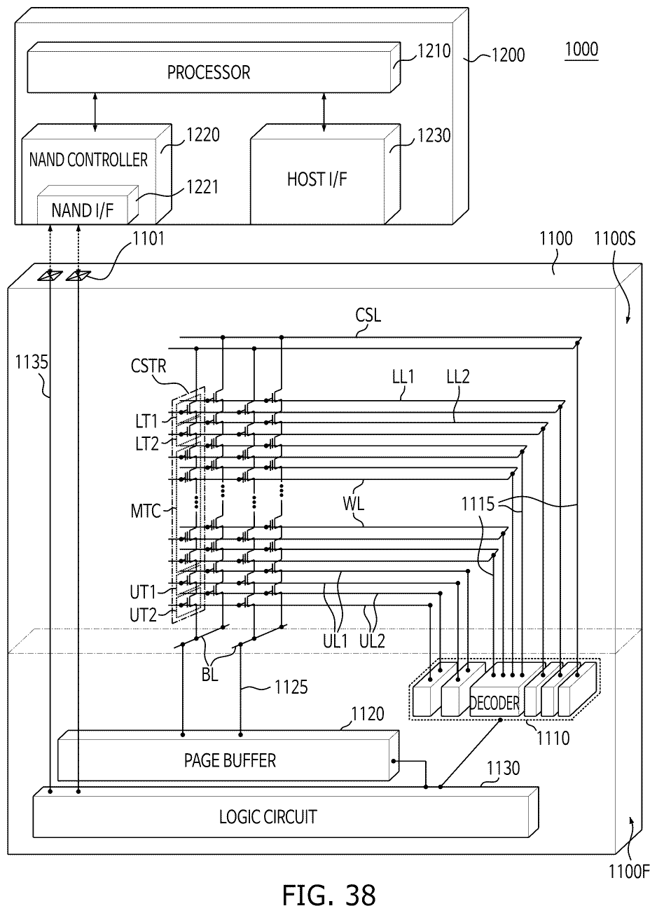

FIG. 38 is an example block diagram illustrating an electronic system according to some example embodiments.

Referring to FIG. 38, an electronic system 1000 according to example embodiments of the present disclosure may include a semiconductor memory device 1100 described above with reference to FIGS. 1-37 and a controller 1200 electrically connected to the semiconductor memory device 1100. The electronic system 1000 may be or may include or be included in a storage device including one or more semiconductor memory devices 1100 and/or an electronic device including such a storage device. For example, the electronic system 1000 may be, may include, or may be included in one or more of an SSD device (solid state drive device), a USB (Universal Serial Bus), a computing system, a medical device, or a communication device that includes one or more semiconductor memory devices 1100.

The semiconductor memory device 1100 may be, for example, a NAND flash memory device described above with reference to FIGS. 1-37. The semiconductor memory device 1100 may include a first structure 1100F and a second structure 1100S on the first structure 1100F. The first structure 1100F may be a peripheral circuit structure including a decoder circuit 1110, a page buffer 1120, and a logic circuit 1130. The second structure 1100S may be a memory cell structure including a bit line BL, a common source line CSL, word lines WL, first and second upper gate lines UL1 and UL2, first and second lower gate lines LL1 and LL2, and memory cell strings CSTR between the bit line BL and the common source line CSL.

In the second structure 1100S, each memory cell string CSTR may include lower transistors LT1 and LT2 adjacent to the common source line CSL, upper transistors UT1 and UT2 adjacent to the bit line BL, and a plurality of memory cell transistors MCT disposed between the lower transistors LT1, LT2 and the upper transistors UT1, UT2. The numbers of the lower transistors LT1, LT2 and the upper transistors UT1, UT2 may vary depending on embodiments.

In some example embodiments, the upper transistors UT1, UT2 may include string select transistors, and the lower transistors LT1, LT2 may include ground select transistors. The lower gate lines LL1, LL2 may each be gate electrodes of the lower transistors LT1, LT2. The word lines WL may be gate electrodes of the memory cell transistors MCT, and the upper gate lines UL1, UL2 may each be gate electrodes of the upper transistors UT1, UT2.

The common source line CSL, the first and second lower gate lines LL1, LL2, the word lines WL, and the first and second upper gate lines UL1, UL2 may be electrically connected to the decoder circuit 1110 via first connection wirings 1115 extending from the first structure 1100F to the second structure 1100S. The bit lines BL may be electrically connected to the page buffer 1120 via second connection wirings 1125 extending from the first structure 1100F to the second structure 1100S.

In the first structure 1100F, the decoder circuit 1110 and the page buffer 1120 may perform a control operation for at least one selected memory cell transistor among the plurality of memory cell transistors MCT. The decoder circuit 1110 and the page buffer 1120 may be controlled by the logic circuit 1130. The semiconductor memory device 1100 may communicate with the controller 1200 through an input/output pad 1101 electrically connected to the logic circuit 1130. The input/output pad 1101 may be electrically connected to the logic circuit 1130 via an input/output connection wiring 1135 extending from the first structure 1100F to the second structure 1100S.

The controller 1200 may include a processor 1210, an NAND controller 1220, and a host interface 1230. According to embodiments, the electronic system 1000 may include a plurality of semiconductor memory devices 1100, and in such a case, the controller 1200 may control the plurality of semiconductor memory devices 1100.

The processor 1210 may control the overall operation of the electronic system 1000, including the controller 1200. The processor 1210 may operate in accordance with predetermined firmware and may access the semiconductor memory device 1100 by controlling the NAND controller 1220. The NAND controller 1220 may include a NAND interface 1221 that processes communication with the semiconductor memory device 1100. Through the NAND interface 1221, control commands for controlling the semiconductor memory device 1100, data to be written to the memory cell transistors MCT of the semiconductor memory device 1100, and data to be read from the memory cell transistors MCT of the semiconductor memory device 1100 may be transmitted. The host interface 1230 may provide a communication function between the electronic system 1000 and an external host. When a control command is received from an external host through the host interface 1230, the processor 1210 may control the semiconductor memory device 1100 in response to the control command.

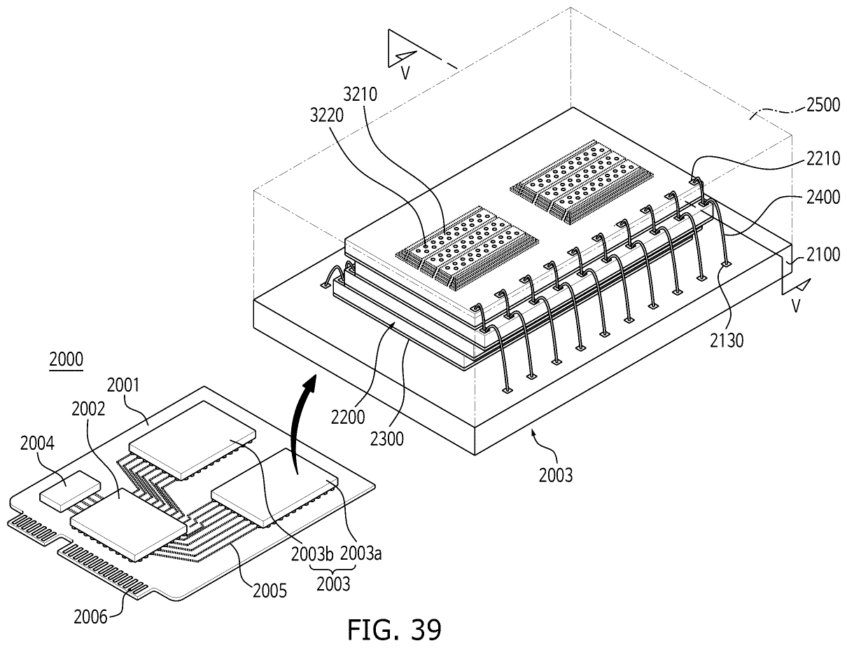

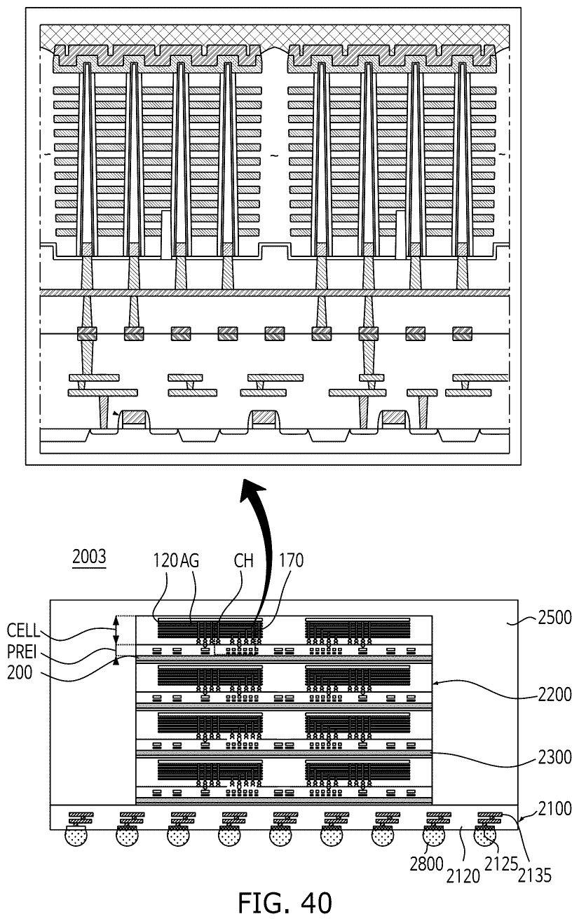

FIG. 39 is an example perspective view illustrating an electronic system including a semiconductor memory device according to some example embodiments. FIG. 40 is a schematic cross-sectional view illustrating FIG. 39 taken along line V-V.

Referring to FIG. 39, an electronic system 2000 according to example embodiments of the present invention may include a main substrate 2001, and a controller 2002, one or more semiconductor packages 2003, and a DRAM 2004 mounted on the main substrate 2001. The semiconductor package 2003 and the DRAM 2004 may be connected to the controller 2002 via wiring patterns 2005 formed on the main substrate 2001.

The main substrate 2001 may include a connector 2006 that includes a plurality of pins coupled to an external host. The number and arrangement of the plurality of pins in the connector 2006 may vary depending on a communication interface between the electronic system 2000 and the external host. In some example embodiments, the electronic system 2000 may communicate with the external host using one or more of various interfaces such as USB (Universal Serial Bus), PCI-Express (Peripheral Component Interconnect Express), SATA (Serial Advanced Technology Attachment), or an M-Phy for Universal Flash Storage (UFS). In example embodiments, the electronic system 2000 may operate on power supplied from the external host through the connector 2006. The electronic system 2000 may further include a PMIC (Power Management Integrated Circuit) that distributes the power supplied from the external host to the controller 2002 and the semiconductor package 2003.

The main controller 2002 may write data to or read data from the semiconductor package 2003, and may improve the operating speed of the electronic system 2000.

The DRAM 2004 may be a buffer memory for alleviating a speed difference between the semiconductor package 2003, which is a data storage space, and the external host. The DRAM 2004 included in the electronic system 2000 may operate as a type of cache memory, and may provide space for temporarily storing data during a control operation of the semiconductor package 2003. When the DRAM 2004 is included in the electronic system 2000, the main controller 2002 may further include a DRAM controller for controlling the DRAM 2004 in addition to an NAND controller for controlling the semiconductor package 2003.

The semiconductor package 2003 may include a first semiconductor package 2003a and a second semiconductor package 2003b spaced apart from each other. Each of the first semiconductor package 2003a and the second semiconductor package 2003b may be a semiconductor package including a plurality of semiconductor chips 2200. Each of the first semiconductor package 2003a and the second semiconductor package 2003b may include a package substrate 2100, the semiconductor chips 2200 on the package substrate 2100, adhesive layers 2300 disposed on lower surfaces of each of the semiconductor chips 2200, a connection structure 2400 that electrically connects the semiconductor chips 2200 to the package substrate 2100, and a molding layer 2500 that covers the semiconductor chips 2200 and the connection structure 2400 on the package substrate 2100.

The package substrate 2100 may be a printed circuit board that includes package upper pads 2130. Each semiconductor chip 2200 may include an input/output pad 2210. The input/output pad 2210 may correspond to the input/output pad 1101 of FIG. 24. Each semiconductor chip 2200 may include metal lines 3210 and channel structures 3220. Each semiconductor chip 2200 may include the semiconductor memory device described above with reference to FIGS. 1-37.

In some example embodiments, the connection structure 2400 may be a bonding wire that electrically connects the input/output pad 2210 and the package upper pads 2130. Therefore, in each of the first semiconductor package 2003a and the second semiconductor package 2003b, the semiconductor chips 2200 may be electrically connected to each other by the bonding wire method, and may also be electrically connected to the package upper pads 2130 of the package substrate 2100. In some example embodiments, in each of the first semiconductor package 2003a and the second semiconductor package 2003b, the semiconductor chips 2200 may be electrically connected to each other by a connection structure including through-silicon vias (TSVs) instead of a bonding wire method.

In some example embodiments, the main controller 2002 and the semiconductor chips 2200 may be included in a single package. In some example embodiments, the main controller 2002 and the semiconductor chips 2200 may be mounted on a separate interposer substrate different from the main substrate 2001, and the main controller 2002 and the semiconductor chips 2200 may be connected to each other through wiring formed on the interposer substrate.

In some example embodiments, the package substrate 2100 may be a printed circuit board. The package substrate 2100 may include a package substrate body 2120, package upper pads 2130 disposed on an upper surface of the package substrate body 2120, lower pads 2125 disposed on or exposed through a lower surface of the package substrate body 2120, and internal wirings 2135 in the package substrate body 2120 that electrically connect the upper pads 2130 and the lower pads 2125. The upper pads 2130 may be electrically connected to the connection structures 2400. The lower pads 2125 may be connected to the wiring patterns 2005 of the main substrate 2001 via conductive connections 2800, as shown in FIG. 39, of the electronic system 2000.

In an electronic system according to some example embodiments, each of or at least one of the semiconductor chips 2200 may include the semiconductor memory device described above with reference to FIGS. 1-16. For example, each or at least one of the semiconductor chip 2200 may include a peripheral circuit structure PERI and a cell structure CELL that is stacked on the peripheral circuit structure PERI. By way of example, the peripheral circuit structure PERI may include the peripheral circuit substrate 200 and the peripheral circuit wiring structure 280 described above with reference to FIGS. 1-37. Additionally, by way of example, the cell structure CELL may include the plurality of gate electrodes 120, the air gap AG, the gate isolation trench WCT, the source plate structure 105, the cell upper insulating layer 180, the barrier layer 150, the cell lower insulating layer 190, the channel structure CH, the support structure 160, the word line contact 170, and so forth, described above with reference to FIGS. 1-37.

Any of the elements and/or functional blocks disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc. The processing circuitry may include electrical components such as at least one of transistors, resistors, capacitors, etc. The processing circuitry may include electrical components such as logic gates including at least one of AND gates, OR gates, NAND gates, NOT gates, etc.

Although certain example embodiments of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the embodiments described above are illustrative and non-limiting in all respects. Furthermore, example embodiments are not necessarily mutually exclusive with one another. For example, some example embodiments may include one or more features described with reference to one or more figures, and may also include one or more other features described with reference to one or more other figures.

What is claimed is:

1. A semiconductor memory device comprising:
a cell lower insulating layer comprising a cell array region and an extension region;
a plurality of gate electrodes stacked spaced apart from each other on the cell lower insulating layer;
a channel structure on the cell array region and penetrating the plurality of gate electrodes;
a word line contact on the extension region and penetrating a portion of gate electrodes among the plurality of gate electrodes;
the semiconductor memory device defining a gate isolation trench penetrating the plurality of gate electrodes and extending in a first horizontal direction;
an air gap between the plurality of gate electrodes and in the gate isolation trench;
a source plate structure defining an opening communicatively coupled to the gate isolation trench, the source plate structure on one end of the channel structure and extending in a second horizontal direction that intersects the first horizontal direction; and
a cell upper insulating layer on the source plate structure and covering the opening,
wherein the air gap is on the cell array region and the extension region.

2. The semiconductor memory device according to claim 1, further comprising:
a barrier layer extending along an upper surface of the cell lower insulating layer; and
a bit line contact penetrating the barrier layer and in the cell lower insulating layer, the bit line contact connected to the channel structure.

3. The semiconductor memory device according to claim 2, further comprising:
a bit line connected to the bit line contact, extending in the second horizontal direction, and in the cell lower insulating layer;
a first bonding pad on a lower surface of the cell lower insulating layer; and
a second bonding pad coupled to the first bonding pad.

4. The semiconductor memory device according to claim 1, wherein
the source plate structure comprises a first side surface on the opening and a second side surface opposite the first side surface in the second horizontal direction, and
the first side surface comprises a first portion having a first slope and a second portion having a second slope different from the first slope.

5. The semiconductor memory device according to claim 1, wherein
the cell upper insulating layer comprises a first protrusion on the opening, and
the first protrusion at least partly overlaps the source plate structure in the second horizontal direction.

6. The semiconductor memory device according to claim 5, wherein a lower surface of the first protrusion comprises a curved surface.

7. The semiconductor memory device according to claim 1, wherein the cell lower insulating layer comprises a plate portion and a second protrusion, the second protrusion protruding toward the gate isolation trench from the plate portion.

8. The semiconductor memory device according to claim 7, further comprising:
a barrier layer extending along an upper surface of the plate portion and an upper surface of the second protrusion.

9. The semiconductor memory device according to claim 7, wherein a distance from the lower surface of the cell lower insulating layer to an upper surface of the second protrusion is greater than a distance from the lower surface of the cell lower insulating layer to a lower surface of the channel structure.

10. The semiconductor memory device according to claim 1, wherein the channel structure comprises:
a semiconductor pattern connected to the source plate structure;
an information storage film surrounding the semiconductor pattern; and
a first high-k insulating film surrounding the information storage film.

11. The semiconductor memory device according to claim 1, further comprising:
a second high-k insulating film surrounding the word line contact.

12. The semiconductor memory device according to claim 1, further comprising:
a support structure around the word line contact and penetrating the plurality of gate electrodes; and
a third high-k insulating film between the support structure and the air gap.

13. The semiconductor memory device according to claim 1, wherein
the source plate structure comprises a semiconductor layer connected to the channel structure and a conductive layer on the semiconductor layer, and
the cell upper insulating layer is in contact with the conductive layer.

14. A semiconductor memory device comprising:
a cell lower insulating layer comprising a cell array region and an extension region;
a barrier layer on the cell lower insulating layer;
a plurality of gate electrodes stacked and spaced apart from each other on the barrier layer;
a channel structure on the cell array region and penetrating the plurality of gate electrodes;
a word line contact on the extension region and connected to one of the plurality of gate electrodes;
the semiconductor memory device defining a gate isolation trench penetrating the plurality of gate electrodes and extending in a first horizontal direction;
an air gap between at least some of the plurality of gate electrodes and in the gate isolation trench;
a source plate structure on one end of the channel structure, extending in a second horizontal direction intersecting the first horizontal direction, and the source plate structure defining an opening communicatively coupled to the gate isolation trench; and
a cell upper insulating layer on the source plate structure and covering the opening,
wherein the air gap is on the cell array region and the extension region.

15. The semiconductor memory device according to claim 14, wherein
the source plate structure comprises a first side surface on the opening and a second side surface facing the first side surface in the second horizontal direction, and
the first side surface comprises a first portion having a first slope and a second portion having a second slope different from the first slope.

16. The semiconductor memory device according to claim 14, further comprising:
a mold insulating layer on a portion between the plurality of gate electrodes,
wherein the air gap surrounds the mold insulating layer.

17. The semiconductor memory device according to claim 14, wherein the plurality of gate electrodes has a staircase shape on the extension region, and each of the plurality of gate electrodes has a different length in the first horizontal direction.

18. The semiconductor memory device according to claim 14, wherein the source plate structure comprises a step, and the air gap is on the step.

19. The semiconductor memory device according to claim 12, wherein the air gap is between the plurality of gate electrodes and the source plate structure.

20. An electronic system comprising:
a main substrate;
a semiconductor memory device mounted on the main substrate, the semiconductor memory device comprising a peripheral circuit structure and a cell structure stacked on the peripheral circuit structure; and
a controller mounted on the main substrate and electrically connected to the semiconductor memory device,
wherein the cell structure comprises,
a cell lower insulating layer comprising a cell array region and an extension region,
a barrier layer on the cell lower insulating layer,
a plurality of gate electrodes stacked and spaced apart from each other on the barrier layer,
a channel structure on the cell array region and penetrating the plurality of gate electrodes;
a word line contact on the extension region and connected to one of the plurality of gate electrodes,
the cell structure defining a gate isolation trench penetrating the plurality of gate electrodes and extending in a first horizontal direction,
an air gap between at least some of the plurality of gate electrodes and in the gate isolation trench,
a source plate structure on one end of the channel structure, extending in a second horizontal direction intersecting the first horizontal direction, the source plate structure defining an opening communicatively coupled to the gate isolation trench, and
a cell upper insulating layer on the source plate structure and covering the opening,
wherein the air gap is on the cell array region and the extension region.
